(19) United States
(12) Patent Application Publication
(10) Pub. No.: US 2025/0096126 A1
(43) Pub. Date: Mar. 20, 2025

(54) BACKSIDE FUSE CONNECTED TO BACKSIDE BACK END OF THE LINE NETWORK

(71) Applicant: INTERNATIONAL BUSINESS MACHINES CORPORATION, ARMONK, NY (US)

(72) Inventors: Dan Moy, Bethel, CT (US); JENS HAETTY, Halfmoon, NY (US); Lawrence A. Clevenger, Saratoga Springs, NY (US); Xiaoming Yang, Clifton Park, NY (US); Brent A. Anderson, Jericho, VT (US); Ruilong Xie, Niskayuna, NY (US); Christopher Murphy, Red Hook, NY (US)

(21) Appl. No.: 18/470,655

(22) Filed: Sep. 20, 2023

(51) Int. Cl. H01L 23/525; H01L 21/762; H01L 21/768; H01L 23/48; H01L 23/62

(52) U.S. Cl. CPC H01L 23/5256; H01L 21/76229; H01L 21/76805; H01L 23/481; H01L 23/62

(57) ABSTRACT

A semiconductor integrated circuit (IC) device that includes a backside fuse structure. The backside fuse structure is located within the backside of the semiconductor IC device and may be vertically located between a microdevice and a backside back end of the line (BEOL) network. The backside fuse structure includes at least a fuse wire. The backside fuse structure may be in a non-programmed state or a programmed state. When in a non-programmed state, an open circuit exists that prevents current flow through the fuse wire. The backside fuse structure may be directly connected to a deep via contact and/or one or more conductive pathways within the backside BEOL network.

### BACKGROUND

The present disclosure relates to fabrication methods and resulting structures for semiconductor devices. More specifically, the present disclosure relates to fabrication methods and resulting semiconductor integrated circuit (IC) devices that include a backside fuse structure, such as an electronic fuse (eFUSE), that is connected to a backside back end of line (BEOL) network.

An eFUSE is a microscopic fuse put into a semiconductor IC device, such as a computer chip, and may provide for the dynamic real-time reprogramming of the semiconductor IC device. Typically, logic is generally “etched” or “hard-wired” into a semiconductor IC device and cannot be changed after the semiconductor IC device has finished being manufactured. By utilizing a set of eFUSEs, a semiconductor IC device manufacturer can allow for the circuits on a chip to change while the chip is in operation. Consequently, eFUSEs may provide semiconductor IC device performance tuning. If certain sub-systems fail, or are taking too long to respond, or are consuming too much power, the semiconductor IC device can instantly change its behavior by blowing or programming one or more eFUSEs. eFUSEs may also be used as a one-time programmable read only memory. This enables writing unique information onto the semiconductor IC device, preventing upgrades or downgrades, or the like.

eFUSEs can be respective silicon or metal traces and typically work (by blowing or programming) by electromigration, the phenomenon by which electric flow causes the conductor material to move. Although electromigration is generally undesired in semiconductor IC device design as it causes failures, eFUSEs are made of weak traces that are designed to fail before others do.

### SUMMARY

In an embodiment of the present disclosure, a semiconductor integrated circuit (IC) device is presented. The semiconductor IC device includes a front end of line (FEOL) microdevice, such as a transistor. The semiconductor IC device further includes a frontside back end of line (BEOL) network and a fuse structure that includes a deep via contact and a fuse wire. The deep via contact is directly connected to a fuse wire and is further directly connected to the frontside BEOL network. The semiconductor IC device further includes a backside contact that is connected to the FEOL microdevice. The semiconductor IC device even further includes a backside BEOL network that includes a conductive pathway, such as a series of vias and wires, that is directly connected to the backside contact and directly connected to the fuse wire. By associating the fuse structure with the backside BEOL network, the presented semiconductor IC device may be further scaled (i.e., shrunk is size) and/or may have reduced signal and/or power wiring routing complexities therein. Further, by placing the fuse wire between the FEOL microdevice and the backside BEOL network, the fuse wire may be located relatively closer to the FEOL microdevice and may require relatively lower (e.g., three to six times lower) programming current compared to known eFUSE placement schemes.

In an example, the fuse wire can be vertically between the deep via contact and the backside BEOL network. By placing the fuse wire vertically between the deep via contact and the backside BEOL network, the fuse wire may be located relatively closer to the FEOL microdevice and may require relatively lower programming current.

In examples, a top surface of the fuse wire can be directly connected to a bottom surface of the deep via contact, a bottom surface of the fuse wire can be directly connected to the conductive pathway, or a bottom surface of the backside contact can be directly connected to the conductive pathway. By structurally associating the fuse wire and the deep via contact with the conductive pathway within the backside BEOL network, the presented semiconductor IC device may be further scaled and/or may have reduced signal and/or power wiring routing complexities therein.

In an example, when the fuse structure is in a non-programmed state, the fuse wire can enable the routing of current through the FEOL microdevice, through the backside BEOL network, and through the frontside BEOL network. In this example, in the non-programmed state, the fuse wire may route current to or from the FEOL microdevice, to the backside BEOL network, to the fusing wire, and to the frontside FEOL network, which may reduce reduced signal and/or power wiring routing complexities therein.

In an example, when the fuse structure is in a programmed state, an open circuit can exist within the fuse wire that prevents the fuse wire from routing current between the frontside BEOL network and the backside BEOL network. In this example, in the programmed state, the fuse wire is prevented from routing current to or from the FEOL microdevice between the backside BEOL network and the frontside FEOL network, which may allow for dynamic real-time reprogramming of the semiconductor IC device.

In an example, the conductive pathway can comprise a plurality of contact vias and one or more backside wires. By associating the fuse structure with the backside BEOL network, the presented semiconductor IC device may be further scaled and/or may have reduced signal and/or power wiring routing complexities therein.

In an example, a bottom surface of the fuse wire can be vertically below a bottom surface of the backside contact. By placing the fuse wire below the backside contact associated with the FEOL microdevice, the fuse wire may be located relatively closer to the FEOL microdevice and may require relatively lower programming current compared to known eFUSE placement schemes.

In an example, the fuse wire can be below a shallow trench isolation (STI) region. This way, the fuse wire may be formed upon the STI region that is known to separate adjacent FEOL microdevices or that is known to be located adjacent to the FEOL microdevice.

In an example, a top surface of the fuse wire can be coplanar with a bottom surface of the backside contact. By placing the fuse wire with such coplanarity with the backside contact that is associated with the FEOL microdevice, the fuse wire may be located relatively closer to the FEOL microdevice and may require relatively lower programming current compared to known eFUSE placement schemes.

In another embodiment of the present disclosure, a semiconductor integrated circuit (IC) device is presented. The semiconductor IC device includes a front end of line (FEOL) microdevice, a backside contact that is connected to the FEOL microdevice, a fuse wire; and a backside BEOL network comprising a first conductive pathway directly connected to the backside contact and directly connected to the fuse wire and a second conductive pathway directly connected to the fuse wire. By associating the fuse wire with the backside BEOL network, the presented semiconductor IC device may be further scaled and/or may have reduced signal and/or power wiring routing complexities therein. Further, by placing the fuse wire between the FEOL microdevice and the backside BEOL network, the fuse wire may be located relatively closer to the FEOL microdevice and may require relatively lower programming current compared to known eFUSE placement schemes.

In an example, the fuse wire can be vertically between the deep via contact and the backside BEOL network. By placing the fuse wire vertically between the deep via contact and the backside BEOL network, the fuse wire may be located relatively closer to the FEOL microdevice and may require relatively lower programming current.

In examples, a top surface of the fuse wire can be directly connected to a bottom surface of the deep via contact, a bottom surface of the fuse wire can be directly connected to the conductive pathway, or a bottom surface of the backside contact can be directly connected to the conductive pathway. By structurally associating the fuse wire and the deep via contact with the conductive pathway within the backside BEOL network, the presented semiconductor IC device may be further scaled and/or may have reduced signal and/or power wiring routing complexities therein.

In an example, when the fuse wire is in a non-programmed state, the fuse wire can enable the routing of current through the FEOL microdevice, through the backside BEOL network, and through the frontside BEOL network. In this example, in the non-programmed state, the fuse wire may route current to or from the FEOL microdevice, to the backside BEOL network, to the fusing wire, and to the frontside FEOL network, which may reduce reduced signal and/or power wiring routing complexities therein.

In an example, when the fuse wire is in a programmed state, an open circuit can exist within the fuse wire that prevents the fuse wire from routing current between the frontside BEOL network and the backside BEOL network. In this example, in the programmed state, the fuse wire is prevented from routing current to or from the FEOL microdevice between the backside BEOL network and the frontside FEOL network, which may allow for dynamic real-time reprogramming of the semiconductor IC device.

In an example, the conductive pathway can comprise a plurality of contact vias and one or more backside wires. By associating the fuse structure with the backside BEOL network, the presented semiconductor IC device may be further scaled and/or may have reduced signal and/or power wiring routing complexities therein.

In an example, a bottom surface of the fuse wire can be vertically below a bottom surface of the backside contact. By placing the fuse wire below the backside contact associated with the FEOL microdevice, the fuse wire may be located relatively closer to the FEOL microdevice and may require relatively lower programming current compared to known eFUSE placement schemes.

In an example, the fuse wire can be below a shallow trench isolation (STI) region. This way, the fuse wire may be formed upon the STI region that is known to separate adjacent FEOL microdevices or that is known to be located adjacent to the FEOL microdevice.

In an example, a top surface of the fuse wire can be coplanar with a bottom surface of the backside contact. By placing the fuse wire with such coplanarity with the backside contact that is associated with the FEOL microdevice, the fuse wire may be located relatively closer to the FEOL microdevice and may require relatively lower programming current compared to known eFUSE placement schemes.

In an example, a semiconductor integrated circuit (IC) device method is presented. The method includes programming a fuse structure that includes a fuse wire and a deep via contact. The deep via contact is directly connected to the fuse wire and directly connected to a frontside back end of the line (BEOL) network. The fuse wire is connected to a conductive pathway within a backside BEOL network. The method further includes, due to programming the fuse structure, preventing current flow between the frontside BEOL network and the backside BEOL network through the fuse wire. In this example, in the programmed state, the fuse wire permits current flow between the backside BEOL network and the frontside FEOL network, which may allow for dynamic real-time reprogramming of the semiconductor IC device.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1A and FIG. 1B depict a semiconductor IC device that includes a fuse structure that is connected to a backside BEOL network, according to one or more embodiments of the disclosure.

FIG. 1C depicts a fuse structure in a non-programmed state and FIG. 1D depicts a fuse structure in a programmed state, according to one or more embodiments of the disclosure.

FIG. 2 through FIG. 22 depict various fabrication structure views of an exemplary semiconductor IC device that includes a fuse structure that is connected to a backside BEOL network, according to one or more embodiments of the disclosure.

FIG. 23 depicts a method of fabricating a semiconductor IC device that includes a fuse structure that is connected to a backside BEOL network, according to one or more embodiments of the disclosure.

FIG. 24 through FIG. 27 depict various fabrication structure views of an exemplary semiconductor IC device that includes a fuse structure that is connected to a backside BEOL network, according to one or more embodiments of the disclosure.

FIG. 28 depicts a method of fabricating a semiconductor IC device that includes a fuse structure that is connected to a backside BEOL network, according to one or more embodiments of the disclosure.

### DETAILED DESCRIPTION

The present disclosure describes an illustrative semiconductor IC device that includes a fuse structure that is connected to a backside back end of line (BEOL) network. In one embodiment, the fuse structure may also be connected to a frontside BEOL network. In an alternative embodiment, the fuse structure is connected to different conductive pathways within the backside BEOL network. In a non-programmed state, the fuse structure may be utilized for routing current between the frontside BEOL network and the backside BEOL network or for routing current between the different conductive pathways within the backside BEOL network. In a programmed state, the fuse structure includes an open circuit that prevents the routing of current thereacross.

In some embodiments, the fuse structure is fabricated after front end of line (FEOL) and prior to backside BEOL network fabrication operations. In FEOL fabrication operations are utilized to fabricate micro devices, such as transistors. Conventional transistors, or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating semiconductor IC device, such as a processor, FPGA, memory module, or the like. In some alternative implementations, the fabrication steps may occur in a different order that that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all of the points of both of the surfaces. Accordingly, two surfaces may be referred to as substantially coplanar despite deviations from coplanarity on an atomic scale, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

For some transistors, integration of the transistors with a backside back end of line (BEOL) network is one of the key challenges to providing increasing packaged IC device densities and performance increases. By incorporating a BEOL network into the semiconductor IC device, there may be a logical and/or functional separation between electrical signal routing and electrical power routing through the semiconductor IC device which may ease routing congestion in some applications. Currently, there is a need to incorporate fuse structures within the backside fabrication stages of the semiconductor IC device. Specifically, there is a need to incorporate fuse structures within the backside fabrication stages, without significant additional fabrication stages and costs associated therewith (e.g., without additional mask and associated lithography stages).

Therefore, the embodiments of the present disclosure may provide a semiconductor IC device that includes a fuse structure that is fabricated in association with one or more microdevice, such as a transistor, diode, memory cell, or the like, fabrication operations. The backside fuse structure may be fabricated after the FEOL microdevice fabrication operations and prior to the backside BEOL network fabrication operations, without significant additional fabrication stages and costs associated therewith. For example, the fuse structure includes a backside fuse wire that is connected to the backside BEOL network and to a deep via which is connected to a frontside BEOL network. The backside fuse wire may be fabricated along with other backside wires during middle of the line (MOL) fabrication, and additional or specific mask and lithography stages to fabricate the backside fuse wire are not necessarily needed.

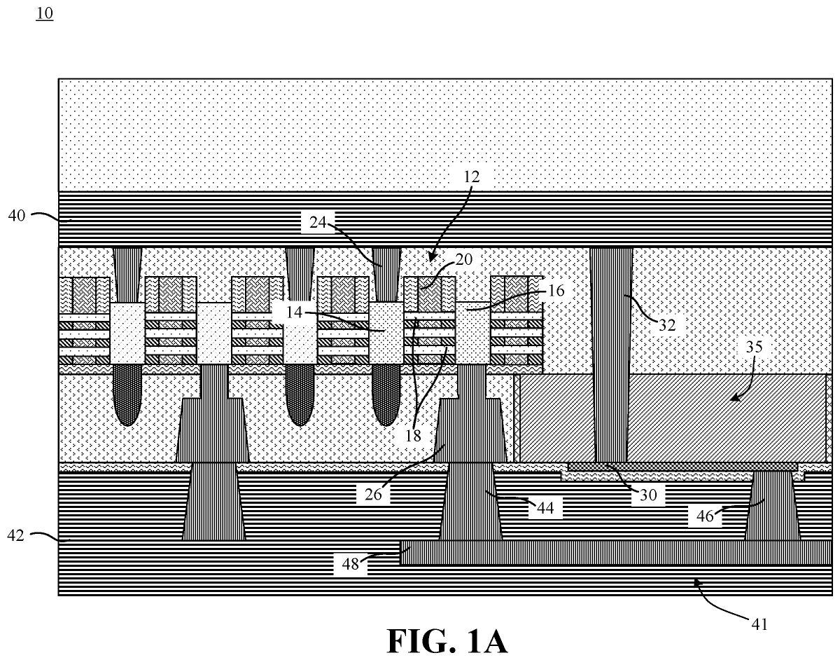

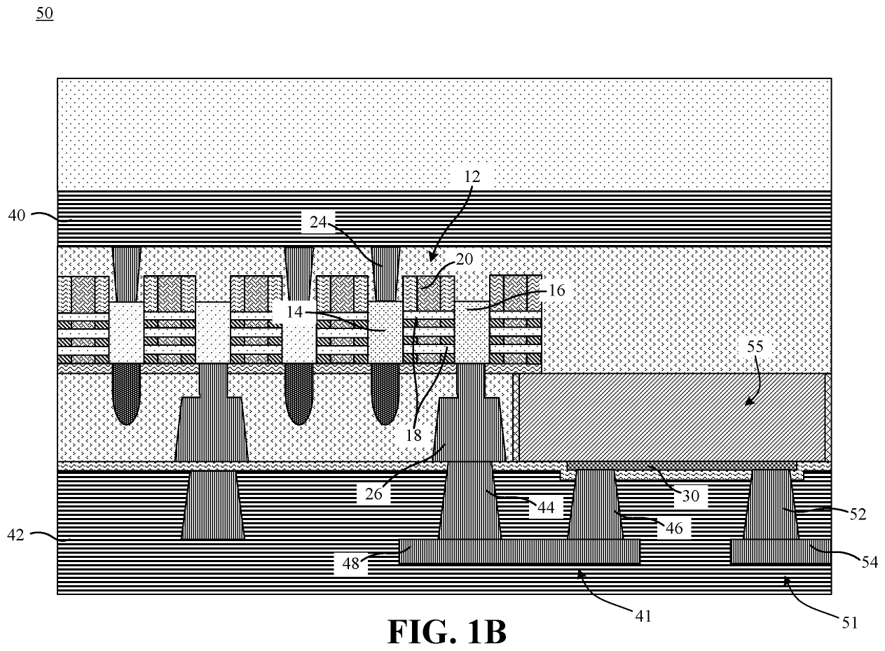

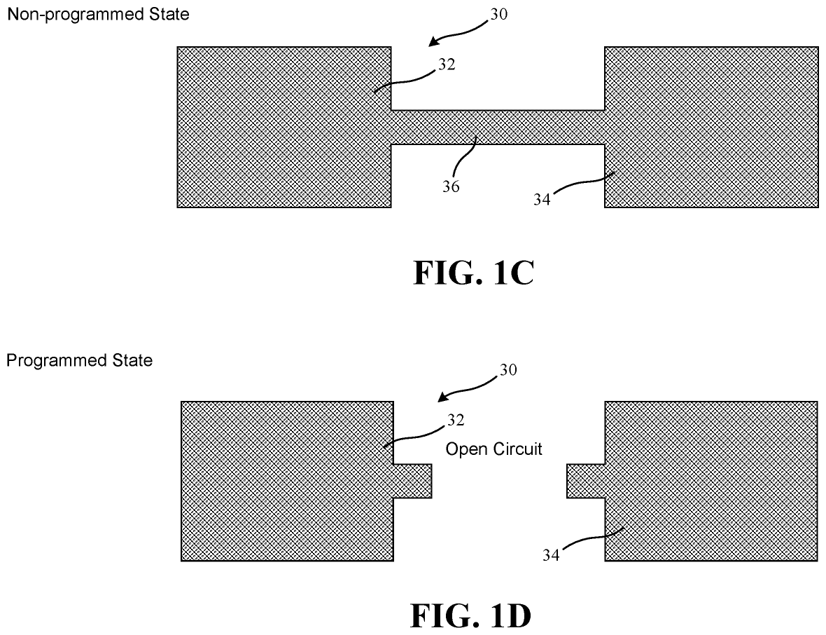

Referring now to FIG. 1A, which depicts an illustrative embodiment of a fuse structure connected to both a frontside BEOL network and a backside BEOL network and to FIG. 1B, which depicts an illustrative embodiment of a fuse structure connected to just a backside BEOL network.

Referring now to FIG. 1A, a cross-sectional view of a semiconductor IC device 10 that includes a fuse structure 35 in a non-programmed state that is connected to a conductive pathway 41 that is located in a backside BEOL network 42 is depicted. Semiconductor IC device 10 may further includes a backside contact 26 that is connected to a transistor 12 and that is connected to the conductive pathway 41 located in backside BEOL network 42. The fuse structure 35 within semiconductor IC device 10 is further connected to a deep via contact 32 that is connected to a frontside BEOL network 40.

Transistor 12 may include a source/drain (S/D) region 14, a S/D region 16, one or more channels 18, and a gate 20. S/D region 14 may be the source of transistor 12 while the S/D region 16 may be the drain of the transistor, or vice versa. The S/D region 14 is connected to the frontside BEOL network 40 by a frontside contact 24. The fuse structure 35 includes a fuse wire 30 and a deep via contact 32. The fuse wire 30 is located vertically between the transistor 12 and the backside BEOL network 42 and is connected to conductive pathway 41 and to the deep via contact 32. The deep via contact 32 is also connected to the frontside BEOL network 40. In the illustrated example, the conductive pathway 41 is located within the backside BEOL network 42 and includes a backside BEOL wire 48, via contact 44, and via contact 46. Via contact 44 is connected to backside contact 26 and to backside BEOL wire 48. Via contact 46 is connected to the fuse wire 30 and to backside BEOL wire 48.

In the non-programmed state of the fuse structure 35, the fuse structure 35 may be utilized for routing current for transistor 12 operation(s). For example, when a voltage that is greater than the threshold voltage of the transistor 12 is applied to the gate 20, electrical current flows through the one or more channels 18, between the S/D region 14 and the S/D region 16. In other words, in the non-programmed state of the fuse structure 35, current may flow through the transistor 12 and through the deep via contact 32 and through the frontside BEOL network 40 by way of the backside BEOL network 42 and the fuse wire 30. In other words, in the non-programmed state of the fuse structure 35, the fuse structure 35 may be used to route current between frontside BEOL network 40 and backside BEOL network 42.

Referring now to FIG. 1B, a cross-sectional view of a semiconductor IC device 50 that includes a fuse structure 55, in a non-programmed state, that is connected to a conductive pathway 41 and to a conductive pathway 51 that are both located in a backside BEOL network 42 is depicted. Semiconductor IC device 50 may further include the backside contact 26 that is connected to transistor 12 and that is connected to the conductive pathway 41.

The fuse structure 55 includes the fuse wire 30. In this illustrated example, the fuse wire 30 is located vertically between the transistor 12 and the backside BEOL network 42 and is connected to conductive pathway 41 and to conductive pathway 51. In the illustrated example, the conductive pathway 41 is located within the backside BEOL network 42 and includes a backside BEOL wire 48, via contact 44, and via contact 46. Via contact 44 is connected to backside contact 26 and to backside BEOL wire 48. Via contact 46 is connected to the fuse wire 30 and to backside BEOL wire 48. Further in the illustrated example, the conductive pathway 51 is also located within the backside BEOL network 42 and includes a backside BEOL wire 54 and a via contact 52. Via contact 52 is connected to fuse wire 30 and to the backside BEOL wire 54.

In the non-programmed state of the fuse structure 55, the fuse structure 55 may be utilized for routing current for transistor 12 operation(s). For example, when a voltage that is greater than the threshold voltage of the transistor 12 is applied to the gate 20, electrical current flows through the one or more channels 18, between the S/D region 14 and the S/D region 16. In other words, in the non-programmed state of the fuse structure 55, current may flow through the transistor 12 and through the backside BEOL network 42 by way of the conductive pathway 41, the fuse wire 30, and the conductive pathway 51. In other words, in the non-programmed state of the fuse structure 55, the fuse structure 55 may be used to route current through the backside BEOL network 42 (e.g., between the conductive pathway 41 and the conductive pathway 51, or the like).

Referring now to FIG. 1C, which depicts a top-down and/or bottom-up view of the semiconductor fuse wire in a non-programmed state. In the non-programmed state, fuse wire 30 allows for current flow thereacross. The fuse wire 30 may have a dog-bone shape with relatively large surface regions 32, 34 that are connected by a trace region 36. Appropriate one or more via contacts 46, one or more via contacts 52, one or more deep via contacts 32, or the like, may be connected to the fuse wire 30 within or upon the large surface regions 32, 34.

Referring now to FIG. 1D, which depicts a top-down or bottom-up view of the fuse wire 30 in a programmed state. In the programmed state, an open circuit is created within the fuse wire 30 that prevents current flow thereacross. Consequently, the open circuit failure within the fuse wire 30, may prevent functionality or operations of the semiconductor IC device that are associated with current flow through the fuse structure, associated with current flow through transistor 12, associated with current flow through the backside BEOL network 42, associated with current flow between backside BEOL network 42 and frontside BEOL network 40, or the like.

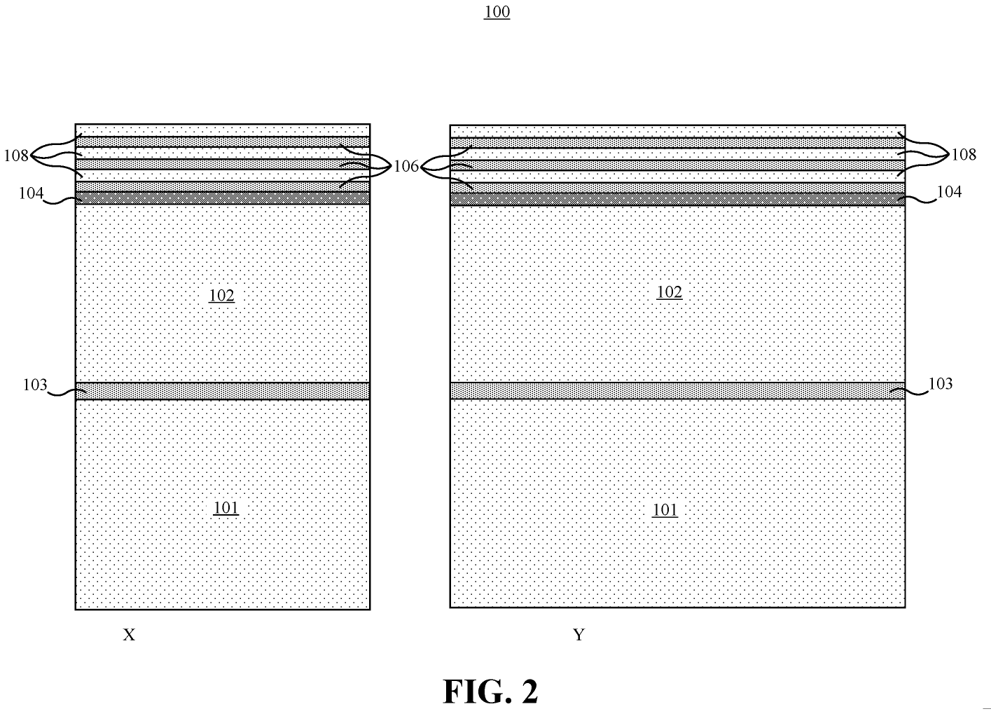

FIG. 2 depicts a cross-sectional view of a semiconductor IC device 100 that includes one or more FEOL microdevices (e.g., one or more GAA FETs) after initial fabrication operations, in accordance with embodiments of the present disclosure. In these initial fabrication stages, nanolayers are formed upon a substrate structure.

The substrate structure may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In the depicted implementation, the substrate structure includes an upper substrate 102, a lower substrate 101, and an etch stop layer 103 between the upper substrate 102 and the lower substrate 101. The upper substrate 102 and the lower substrate 101 may be comprised of any other suitable material(s) that those listed above, and the etch stop layer 103 may be a dielectric material with etch selectivity to one or both of the upper substrate 102 and/or the lower substrate 101. In one example, the etch stop layer 103 may be an oxide and the substrate structure may be referred to as a buried oxide (BOX) substrate. In another example, the lower substrate 101 may be composed of Si. The etch stop layer 103 may be composed of Silicon Germanium (SiGe) and may be epitaxially grown from the top surface of lower substrate 101 and the upper substrate 102 may be composed of Si and may be epitaxially grown from the top surface of etch stop layer 103.

Nanolayers may be formed over the substrate structure by forming a bottom sacrificial nanolayer 104 and by forming a series of alternating sacrificial nanolayers 106 and active nanolayers 108 thereupon. In certain examples, the bottom sacrificial nanolayer 104 is initially formed directly on an upper surface of the substrate structure. In other examples, certain layer(s) may be formed between the upper surface of the substrate structure and the bottom sacrificial nanolayer 104. In an example, the bottom sacrificial nanolayer 104 may be formed by epitaxially growing a SiGe layer with high Ge %, ranging from 50% to 70%. The bottom sacrificial nanolayer 104 generally has etch selectivity relative to the sacrificial nanolayers 106 and active nanolayers 108.

The nanolayers may be further formed by fabricating the alternating series of sacrificial nanolayers 106, such as SiGe sacrificial nanolayers, and active nanolayers 108, such as Si nanolayers, upon the bottom sacrificial nanolayer 104. The sacrificial nanolayers 106 can have Ge % ranging from 20% to 45%. In an implementation, the alternating active sacrificial nanolayer 106 and active nanolayer 108 may be formed by epitaxially growing one layer and then the next until the desired number and desired thicknesses of the layers are achieved. Any number of alternating nanolayers can be provided. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

In the illustrated semiconductor IC device 100, there are a total of three sacrificial nanolayers 106 and three active nanolayers 108. However, it should be appreciated that any suitable number of alternating nanolayers may be formed. Although it is specifically contemplated that the bottom sacrificial nanolayer 104 and the sacrificial nanolayers 106 can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the bottom sacrificial nanolayer 104, the sacrificial nanolayers 106, and the active nanolayers 108 are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

In certain embodiments, the nanolayers have a vertical thickness ranging, for example, from approximately 3 nm to approximately 20 nm. In certain embodiments, the nanolayers have a vertical thickness ranging, for example, from approximately 3 nm to approximately 10 nm. Although the range of 3-20 nm is cited as an example range of thickness of the nanolayers, other thickness of these nanolayers may be used. In certain examples, certain of the nanolayers may have different thicknesses relative to one another. In certain examples, it may be desirable to have a small vertical spacing (VSP) between adjacent active nanolayers 108 to reduce the parasitic capacitance and to improve circuit speed. For example, the VSP (the distance between adjacent active nanolayers 108) may range from 5 nm to 15 nm. However, the VSP must be of a sufficient value to accommodate the gate that will be formed in the spaces created by later removal of respective portions of the sacrificial nanolayers 106.

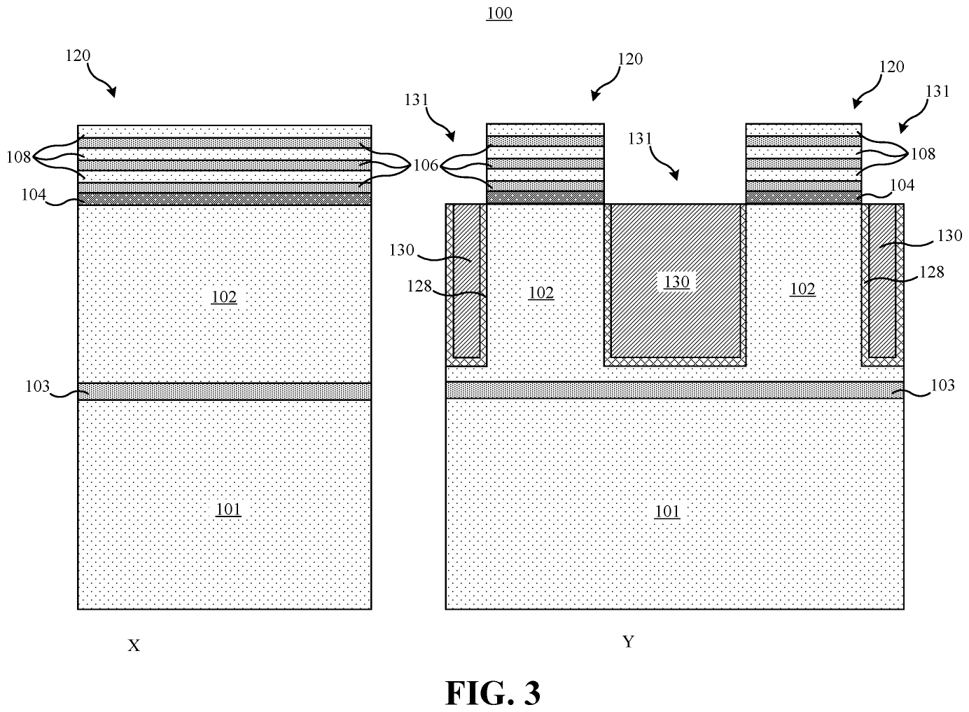

FIG. 3 depicts cross-sectional views of the semiconductor IC device 100 after fabrication operations, in accordance with embodiments of the present disclosure. In the depicted fabrication stages, the nanolayers are patterned into nanolayer stacks 120 and shallow trench isolation (STI) regions are formed.

To form one or more nanolayer stacks 120, a mask layer (not shown) may be formed on the uppermost nanolayer. The mask layer may be comprised of any suitable mask material(s). The mask layer may be patterned and used to perform the nanolayer stack 120 patterning process. In the nanolayer stack 120 patterning process, any suitable material removal process (e.g., reactive ion etching or RIE) may be used to remove portions of the alternating nanolayers down to the level of the substrate structure, or the like. Following the nanolayer stack 120 patterning process, one or more nanolayer stacks 120 are formed. Subsequently, the mask layer may be removed.

The removal of undesired portion(s) of the alternating nanolayers may further remove undesired portions of substrate structure that are adjacent to respective footprints of nanolayer stacks 120 to form STI region openings. The etch may be timed or otherwise controlled to stop the removal of the substrate structure such that the depth or bottom of the one or more STI region openings has a predetermined or desired dimension. For example, the depth or bottom of the one or more STI region openings may be above the etch stop layer 103, as depicted. In some examples, the etch to form the nanolayer stacks 120 may utilize the etch stop layer 103 to stop the etch and form the bottom of the one or more STI region openings.

A STI region may be formed upon and/or within the substrate structure within respective STI region openings. For example, one or more STI regions 131 may be formed by depositing electrical dielectric material(s) within respective STI region opening(s) that are adjacent to the one or more nanolayer stacks 120 (e.g., to the front and rear of one or more nanolayer stacks 120), as depicted. For clarity, one or more other STI regions 131 may be formed by depositing electrical dielectric material(s) within respective STI region opening(s) that are adjacent to the one or more nanolayer stacks 120 (e.g., to the side of one or more nanolayer stacks 120).

A top surface of the one or more STI regions 131 may be coplanar with a top surface of the substrate structure. The one or more STI regions 131 may have a volume that sufficiently electrically isolates components or features of neighboring transistors, or the like, and/or may sufficiently electrically isolate neighboring nanolayer stacks 120.

In an example, the STI region(s) 131 may be formed by depositing a STI liner 128 within the STI region openings. Subsequently, STI region(s) 131 may be further formed by depositing STI dielectric material 130 upon the STI liner 128. A etch back, recess, or the like, may occur to remove undesired or over formed STI liner 128 and/or STI dielectric material 130, such that the top surface of the STI region(s) 131 are coplanar with a bottom surface of the bottom sacrificial nanolayer 104. STI liner 128 may be composed of but not limited to a nitride, low-k nitride, or the like. The STI dielectric material 130 may be composed of but not limited to an oxide, low-k oxide, or the like.

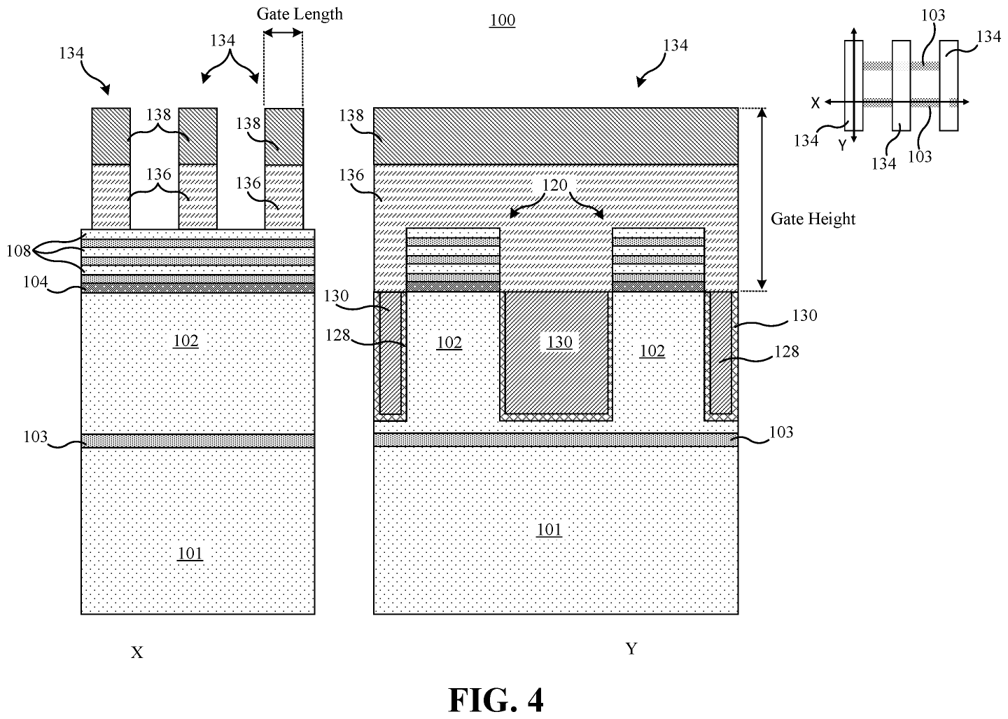

FIG. 4 depicts cross-sectional views of the semiconductor IC device 100 after fabrication operations, in accordance with embodiments of the present disclosure. In the depicted fabrication stages, one or more sacrificial gate structures 134 are formed upon STI regions 131 and upon and around the one or more nanolayer stacks 120. The one or more sacrificial gate structures 134 may include a sacrificial gate liner (not shown), a sacrificial gate 136, and a sacrificial gate cap 138.

The sacrificial gate structures 134 may be formed by initially depositing a sacrificial gate liner layer (e.g., a dielectric, oxide, or the like) upon the one or more STI regions 131 and upon and around the one or more nanolayer stacks 120. The sacrificial gate structures 134 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer stacks 120. The sacrificial gate structures 134 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 134 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 136, and the sacrificial gate cap 138, respectively, of each of the one or more sacrificial gate structures 134.

One or more sacrificial gate structures 134 can be formed on targeted regions or areas of semiconductor IC device 100 to define the length of one or more GAA FETs and to provide sacrificial material for yielding targeted GAA FET structure(s) in subsequent processing. According to an example, each sacrificial gate structure 134 can have a height of between approximately 50 nm and approximately 200 nm, and a length of between approximately 10 nm and approximately 200 nm.

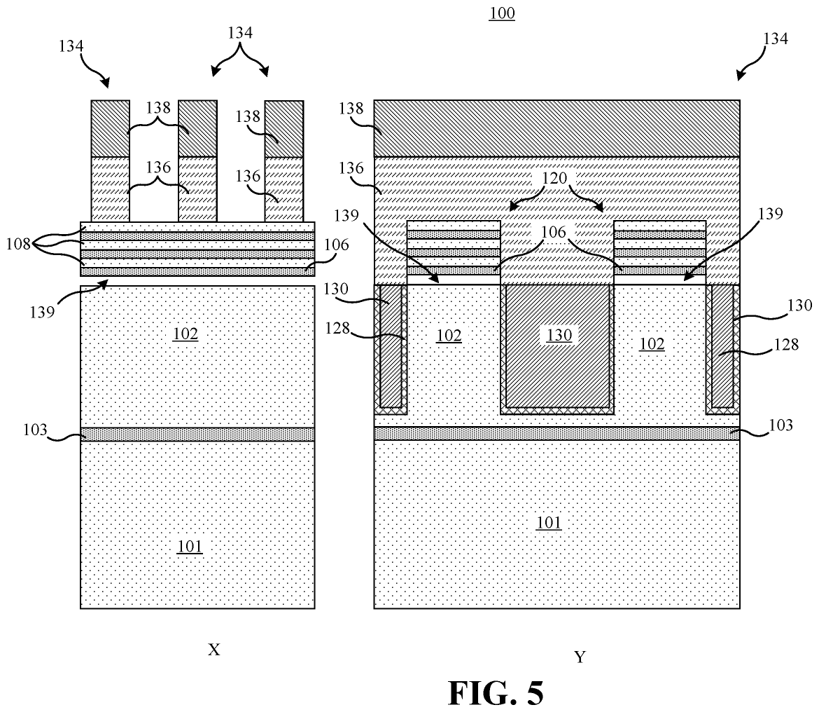

FIG. 5 depicts cross-sectional views of the semiconductor IC device 100 after fabrication operations, in accordance with embodiments of the present disclosure. In the depicted fabrication stages, bottom sacrificial nanolayer 104 is selectively removed.

The bottom sacrificial nanolayer 104 may be selectively removed by a wet etch utilizing an etchant that targets the material if the bottom sacrificial nanolayer 104 selective to the respective material(s) of the sacrificial nanolayers 106, the active nanolayers 108, STI region(s) 131, and/or sacrificial gate structures 134, as appropriate. The etch may be timed or otherwise controlled to effectively remove the bottom sacrificial nanolayer 104 while substantially retaining the sacrificial nanolayers 106, the active nanolayers 108, the STI region(s) 131, and the sacrificial gate structures 134, etc. As depicted, the removal of bottom sacrificial nanolayer 104 forms a bottom dielectric isolation (BDI) cavity 139 between the substrate structure and the bottommost sacrificial nanolayer 106.

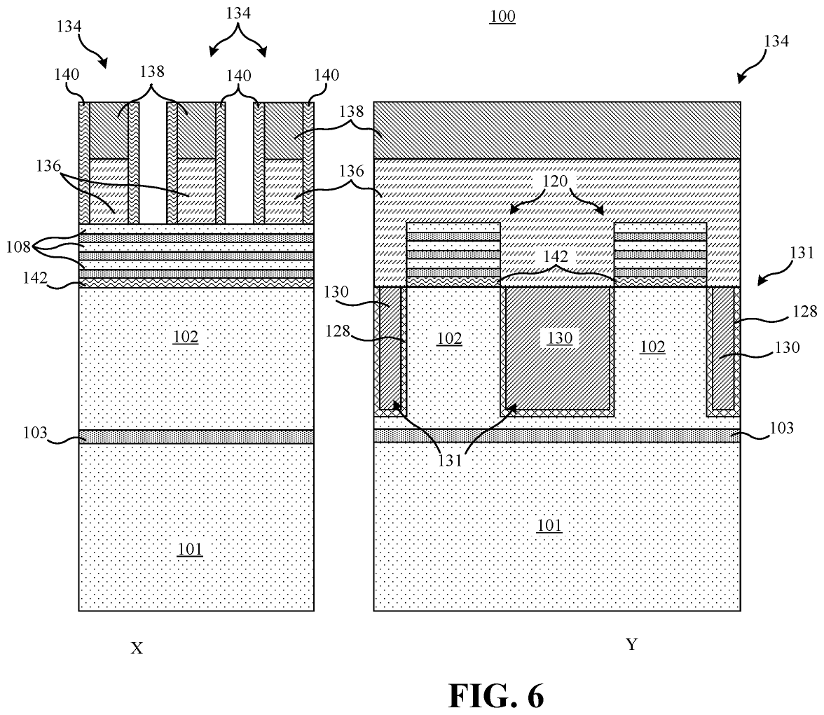

FIG. 6 depicts cross-sectional views of the semiconductor IC device 100 after fabrication operations, in accordance with embodiments of the present disclosure. In the depicted fabrication stages, gate spacers 140 and BDI region 142 are formed.

The BDI region 142 is formed within a respective BDI cavity 139 within the one or more nanolayer stacks 120. The gate spacer(s) 140 are formed upon the sidewall(s) of the sacrificial gate structures 134, upon the STI region(s) 131 (not shown in the depicted cross sections), and around the one or more nanolayer stacks 120.

The BDI region 142 and the gate spacer(s) 140 may be simultaneously formed by a conformal deposition of a dielectric material, such as silicon nitride, SiBCN, SiNC, SiN, SiCO, SiNOC, or a combination thereof, or the like, within the nanolayer cavity 139, upon STI regions 131, upon around the one or more sacrificial gate structures 134, and upon and around the one or more nanolayer stack(s) 120. Subsequently, undesired portions of dielectric material may be removed while desired portions the dielectric material may be retained and thereby form the BDI region 142 and the gate spacer(s) 140. The undesired portions of dielectric material may be removed by a directional ion etch, such as a reactive ion etch (RIE). The RIE may remove exposed or unprotected horizontal portions of the dielectric material while retaining protected horizontal portions of the dielectric layer (e.g., the BDI region 142) and vertical portions of the dielectric layer (e.g., the gate spacers 140).

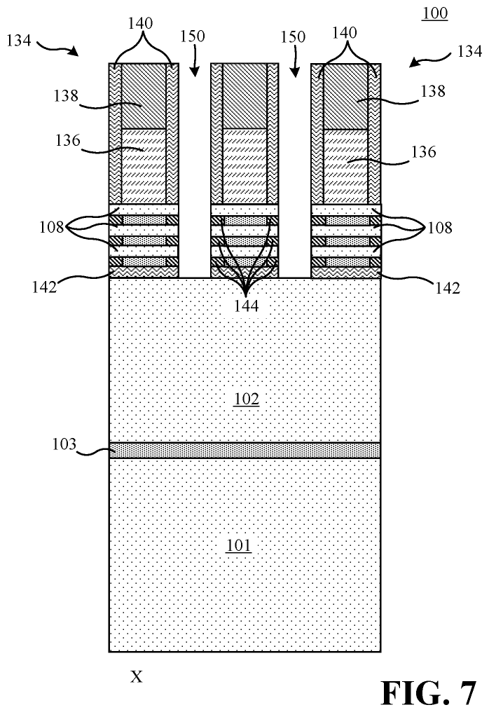

FIG. 7 depicts a cross-sectional view of the semiconductor IC device 100 after fabrication operations, in accordance with embodiments of the present disclosure. In the depicted fabrication stages, source/drain (S/D) recesses 150 are formed within the one or more nanolayer stacks 120 between gate spacers 140 of neighboring sacrificial gate structures 134. In other words, a single nanolayer stack 120 may be separated, by S/D recesses 150, into multiple nanolayer stacks 120 each located underneath a respective sacrificial gate structure 134. Further in the depicted fabrication stages, sacrificial nanolayers 106 are indented and a respective inner spacer 144 is formed in each indent.

The one or more S/D recesses 150 may be formed between adjacent sacrificial gate structures 134 by removing respective portions of the sacrificial nanolayers 106, active nanolayers 108, BDI region 142 that are between gate spacers 140 of adjacent or neighboring sacrificial gate structures 134. The one or more S/D recesses 150 may be formed to a depth to stop at the top surface of the substrate structure (e.g., the top surface of upper substrate 102, or the like), the top surface of STI regions 131, or the like.

The undesired portions of sacrificial nanolayers 106, active nanolayers 108, and BDI region 142 may be removed by etching or other subtractive removal techniques. The top surface of the substrate structure may be used as an etch stop or other etch parameters may be controlled to stop the material removal at the substrate structure. As the gate spacers 140 and the sacrificial gate structures 134 may be utilized to protect the underlying portions of sacrificial nanolayers 106, active nanolayers 108, and BDI region 142, respective sidewalls of the nanolayer stacks 120 may be substantially coplanar with the outer sidewalls of the gate spacers 140 there above.

Further, in the depicted fabrication stages, indents are formed by laterally or horizontally removing respective portions of sacrificial nanolayers 106 within the nanolayer stacks 120. The indents may be formed by a reactive ion etch (RIE) process, which can remove portions of the sacrificial nanolayers 106. The horizontal depth of the indents may be chosen to set a length for the replacement gate structure formed in place of the sacrificial gate structure 134. When the sacrificial nanolayers 106 are composed of SiGe, the directional RIE can use a boron-based chemistry or a chlorine-based chemistry, for example, which recesses or removes the exposed end portions of sacrificial nanolayers 106 (e.g., end portions of sacrificial nanolayers 106 generally below spacer 140) selective to the Si active nanolayers 108. In alternative implementations when sacrificial nanolayers 106 are not SiGe and when active nanolayers 108 are not Si, the directional etch of the sacrificial nanolayers 106 may generally be selective to the active nanolayers 108, gate spacers 140, STI regions 131, and/or substrate structure.

Further, in the depicted fabrication stages, a respective inner spacer 144 is formed within each indent. The one or more inner spacers 144 can be formed by ALD or CVD or any other suitable deposition technique that deposits a dielectric material within the indent(s), thereby forming the inner spacer(s) 144. In some examples, the inner spacer(s) 144 are composed of a low-κ dielectric material (a material with a lower dielectric constant relative to SiO₂), SiN, SiO, SiBCN, SiOCN, SiCO, etc. or any other suitable dielectric material. In certain implementations, after the formation of the inner spacer(s) 144, an isotropic etch process is performed to create outer vertical surfaces or sidewalls of the inner spacer(s) 144 that are coplanar with the outer vertical surfaces or sidewalls of the active nanolayers 108, of the gate spacers 140, and/or of the BDI region 142.

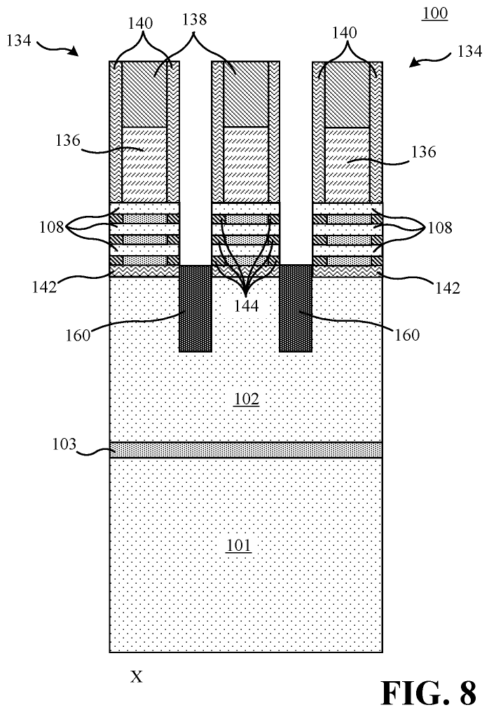

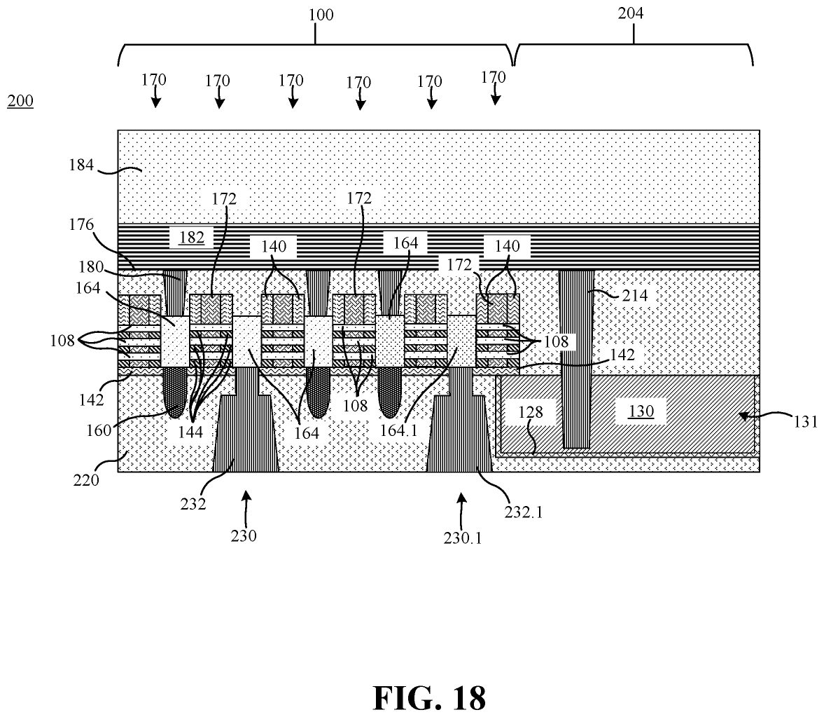

FIG. 8 depicts a cross-sectional view of the semiconductor IC device 100 after fabrication operations, in accordance with embodiments of the present disclosure. In the depicted fabrication stages, one or more backside contact placeholders 160 are formed within the substrate structure in between adjacent sacrificial gate structures 134. In one example, the one or more backside contact placeholders 160 may be formed only in locations in which a backside contact, such as backside contact 230 depicted in FIG. 18, or the like, is to be formed. In an alternative example, a respective backside contact placeholder 160 may be formed in location(s) in which a backside contact is to be formed and in location(s) where a backside contact is not to be formed.

The one or more backside contact placeholders 160 may be formed by initially forming one or more backside contact placeholder cavities within the substrate structure generally in between adjacent sacrificial gate structures 134 and underneath respective one or more S/D recesses 150 (depicted in FIG. 7). For example, the one or more backside contact placeholder(s) cavities may be formed by a subtractive removal technique, such as an etch, that removes associated portion(s) of the upper substrate 102. The etch may be timed or otherwise controlled to stop the removal of the upper substrate 102 such that the depth or bottom of the one or more backside contact placeholder(s) cavities are above the etch stop layer 103, as depicted.

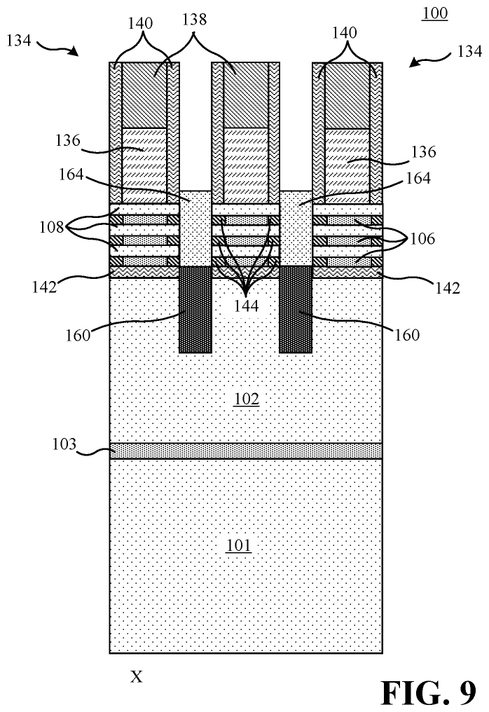

The one or more backside contact placeholders 160 may be further formed by epitaxially growing an epitaxial material from exposed substrate structure surface(s) within the one or more backside contact placeholder(s) cavities. In some embodiments, epitaxial growth and/or deposition processes may be selective to forming on the semiconductor surfaces of the upper substrate 102, and may not deposit material on dielectric surfaces, such as silicon dioxide or silicon nitride surfaces. In some embodiments, the epitaxial growth of the one or more backside contact placeholders 160 may overgrow above the top surface of the substrate structure or above the top surface of BDI region(s) 142. In an example, the epitaxial material of the one or more backside contact placeholders 160 may be chosen to be etch selective to the material of the S/D region(s) 164, exemplarily depicted in FIG. 9, the material of the upper substrate 102, or the like. In another example, an etch stop layer (not shown) is formed upon the top surface of the backside contact placeholders 160. For example, the one or more backside contact placeholders 160 may be SiGe and a Si etch stop layer may be epitaxially grown from the top surface of the SiGe backside contact placeholders 160. Respective top surfaces of the backside contact placeholders 160 (or etch stop layer thereupon) may be substantially horizontal and below the bottom surface of the bottommost active nanolayer 108 (e.g., to enable contact between such active nanolayer 108 and the S/D region 164, as depicted in FIG. 9) and/or substantially coplanar with a respective one or more top surface(s) of BDI region 142.

FIG. 9 depicts a cross-sectional view of the semiconductor IC device 100 after fabrication operations, in accordance with embodiments of the present disclosure. In the depicted fabrication stages, a respective S/D region 164 is formed upon a backside contact placeholder 160 (if present) or upon the substrate structure (if backside contact placeholder 160 is not present) in between adjacent sacrificial gate structures 134.

The S/D region 164 forms either a source or a drain, respectively, of respective GAA FET and is connected to respective a side or end surface of the active nanolayers 108 of a nanolayer stack 120. The S/D region 164 is composed of a semiconductor material and a dopant. As used herein, a “source/drain” region can be a source region or a drain region depending on subsequent wiring and application of voltages during operation of the transistor. The semiconductor material that provides each of the S/D region 164 is composed of one of the semiconductor materials mentioned above for the semiconductor structure. The semiconductor material that provides the S/D region 164 can be compositionally the same, or compositionally different from each active nanolayers 108. The dopant that is present in the S/D region 164 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the S/D region 164 can have a dopant concentration of from 4×10²⁰ atoms/cm³ to 3×10²¹ atoms/cm³.

The one or more S/D regions 164 may be epitaxially grown or formed. In some examples, the S/D region 164 are formed by in-situ doped epitaxial growth. The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, the S/D epitaxial growth conditions that promote in-situ Boron doped SiGe for p-type transistor and phosphorus or arsenic doped silicon or Si:C for n-type transistors.

In some examples, the epitaxial growth that forms the one or more S/D region 164 occurs or is promoted from the top surface of upper substrate 102, from the upper surface of backside contact placeholders 160 (or etch stop layer thereupon), while epitaxial growth is limited or does not occur from neighboring STI regions 131.

In some embodiments, epitaxial growth to form the one or more bottom S/D regions 164 may overgrow above the upper surface of the semiconductor IC device 100 and be subsequently recessed such that the top surface of the S/D region 164 is above the top surface of the topmost active nanolayer 108 within the first series of nanolayers (e.g., to enable contact between such active nanolayer 108 and the S/D region 164).

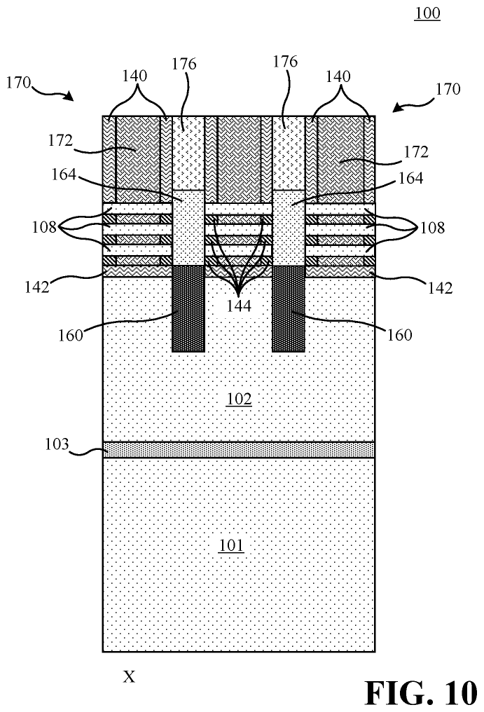

FIG. 10 depicts a cross-sectional view of the semiconductor IC device 100 after fabrication operations, in accordance with embodiments of the present disclosure. In the depicted fabrication stages, an interlayer dielectric (ILD) 176 is formed. For example, ILD 176 may be formed upon the S/D region 164 and upon at least the sidewalls of the gate spacers 140 associated with adjacent sacrificial gate structures 134. Further, in the depicted fabrication stages, the sacrificial gate structures 134 are removed and a replacement gate structure 170 is formed in place thereof.

The ILD 176 may be formed by depositing a blanket dielectric material. The ILD 176 can be any suitable material, such as, for example, porous silicates, carbon doped oxides, silicon dioxides, silicon nitrides, silicon oxynitrides, organic planarization material (OPL), or other dielectric materials. Any known manner of forming the ILD 176 can be utilized. The ILD 176 can be formed using, for example, CVD, PECVD, ALD, flowable CVD, spin-on dielectrics, or PVD.

In an example, the ILD 176 may be formed to a thickness above the top surface of the sacrificial gate structures 134. Subsequently, a planarization process, such as a CMP, may be performed to remove excess ILD 176 material, to remove the sacrificial gate caps 138, and to partially remove the gate spacers 140. The planarization may also partially remove some of the sacrificial gate 136 or may at least expose the sacrificial gate 136 of the sacrificial gate structures 134. The CMP may create a planar or horizontal top surface for the semiconductor IC device 100. In other words, the respective top surfaces of ILD 176, gate spacers 140, sacrificial gates 136 may be coplanar.

Further, in the depicted fabrication stages, the sacrificial gate structures 134 are removed and a replacement gate structure 170 is formed in place thereof. The sacrificial gate structures 134 may be removed by initially removing the sacrificial gate 136 and sacrificial gate oxide by a removal technique, such as one or more series of etches. For example, such removal may be accomplished by a wet chemical etching process in which one or more chemical etchants are used to remove the sacrificial gate 136 and sacrificial gate oxide of the sacrificial gate structures 134. Appropriate etchants may be used that remove the sacrificial gate 136 and/or sacrificial gate oxide selective to the active nanolayers 108, inner spacers 144, gate spacers 140, BDI region 142, STI regions 131, and substrate structure, or the like.

Next, the active nanolayers 108 may be released by removing the sacrificial nanolayers 106. The sacrificial nanolayers 106 may be removed by a removal technique, such as one or more series of etches. For example, the etching can include a wet chemical etching process in which one or more chemical etchants are used to remove the sacrificial nanolayers 106. Appropriate etchants may be used that remove the sacrificial nanolayers 106 selective to the active nanolayers 108, inner spacers 144, BDI region 142, gate spacers 140, or the like. After the removal of sacrificial nanolayers 106, there are void spaces above and/or below the active nanolayers 108.

Further, in the depicted fabrication stages, a replacement gate structure 170 is formed in place of the removed sacrificial gate structures 134 around the active nanolayers 108, and upon BDI region 142.

Replacement gate structure(s) 170 may be formed by initially forming an interfacial layer on the gate spacers 140, on the active nanolayers 108, on the BDI region 142, on the inner spacers 144, etc. that are interior to and/or upon the respective surfaces interior to the opening created by the removal of the sacrificial gate structure 134 and releasing of the active nanolayers 108. The interfacial layer can be deposited by any suitable techniques, such as ALD, CVD, PVD, thermal oxidation, combinations thereof, or other suitable techniques.

Replacement gate structure(s) 170 may be further formed by forming a high-κ layer to cover the exposed surfaces of the interfacial layer. The high-κ layer can be deposited by any suitable techniques, such as ALD, CVD, metal-organic CVD (MOCVD), PVD, thermal oxidation, combinations thereof, or other suitable techniques. A high-κ material is a material with a higher dielectric constant than that of SiO₂, and can include e.g., LaO, AlO, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The high-κ layer can include a single layer or multiple layers, such as metal layer, liner layer, wetting layer, and adhesion layer. In other embodiments, the high-κ layer can include, e.g., Ti, Ag, Al, TiAlN, TaC, TaCN, TaSiN, Mn, Zr, TiN, TaN, Ru, Mo, Al, WN, Cu, W, or any suitable materials.

Replacement gate structure(s) 170 may be further formed by depositing a work function (WF) gate upon the high-κ layer. The WF gate can be comprised of a conductor or metal, such as, e.g., copper (Cu), cobalt (Co), aluminum (Al), platinum (Pt), gold (Au), tungsten (W), titanium (Ti), nitride (N³) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In general, the WF gate sets the threshold voltage (Vt) of the device. The high-κ layer may separate the WF gate from the nanolayer channel (i.e., active nanolayer 108). Other metals that may be desired to further fine tune the effective work function (eWF) and/or to achieve a desired resistance value associated with current flow through the gate in the direction parallel to the plane of the nanolayer channel.

The one or more replacement gate structure(s) 170 may be further formed by depositing a conductive fill gate 172 upon the WF gate. The conductive fill gate 172 can be comprised of a conductor material and/or metal, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 170 formation, the top surface of the semiconductor IC device 100 may be planarized by a planarization technique such as a CMP, mechanical grinding process, or the like. After the planarization technique, respective top surfaces of the ILD 176, gate spacers 140, replacement gate structure(s) 170, may be substantially horizontal and/or may be substantially coplanar.

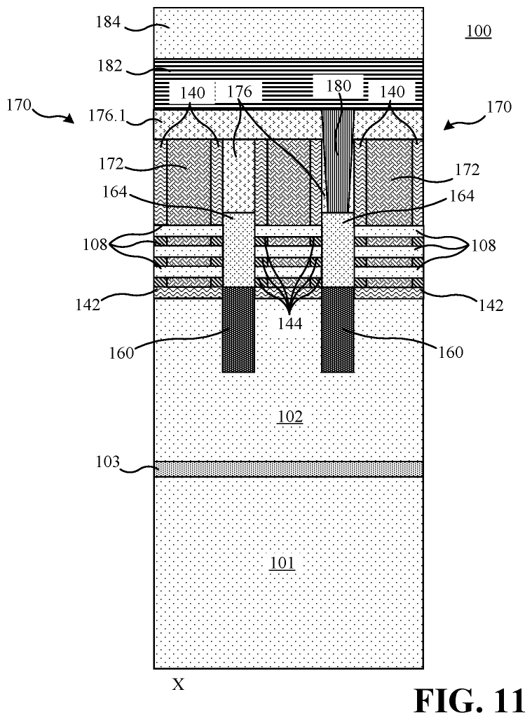

FIG. 11 depicts cross-sectional views of the semiconductor IC device 100 after fabrication operations, in accordance with embodiments of the present disclosure. In the depicted fabrication stages, ILD 176.1 is formed, one or more frontside contact(s) 180 are formed, a frontside BEOL network 182 is formed, and a carrier wafer 184 is attached.

The ILD 176.1 may be formed upon respective top surfaces of replacement gate structure 170 and ILD 176. The ILD 176.1 may be formed by depositing a dielectric material, such as, for example, porous silicates, carbon doped oxides, silicon dioxides, silicon nitrides, silicon oxynitrides, or other dielectric materials. Any appropriate deposition technique for forming the ILD 176.1 can be utilized. The ILD 176.1 can be formed using, for example, CVD, PECVD, ALD, flowable CVD, spin-on dielectrics, or PVD.

The frontside contact(s) 180 may be formed by patterning respective frontside contact openings within ILD 176.1, ILD 176, or the like, from the frontside (i.e., from above the semiconductor IC device 100, as depicted, downward to respective structures thereof). The frontside contact(s) 180 may be in direct or indirect physical and electrical contact and/or may physically meld with respective material(s) of one or more regions of the semiconductor IC device 100. For example, frontside contact 180 is in direct contact with S/D region 164. Similarly, another frontside contact 180 (not shown) may be in direct contact with replacement gate structure 170.

The frontside contact(s) 180 may be formed by initially forming frontside contact opening(s). The frontside contact opening(s) may be formed by the same or shared lithography and etch process(es), or sequential lithography and etch processes. In such process(es), a mask may be applied and patterned. An opening in the patterned mask may expose the portion of the underlying ILD 176.1 to be removed while other protected portions of semiconductor IC device 100 thereunder may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention.

The frontside contact(s) 180 may be further formed by depositing conductive material such as metal into the respective frontside contact opening(s). In an example, frontside contact(s) 180 may be formed by depositing a liner, such as Ni, NiPt or Ti, etc. into the contact opening(s), depositing a metal adhesion liner, such as TiN, TaN, etc. upon the liner, and by depositing a conductive metal fill, such as Al, Ru, W, Co, Cu, etc. upon the metal adhesion liner. Subsequently, a planarization process, such as a CMP process or a mechanical grinding process, may remove excess portions of the conductive barrier layer and the conductive material. Subsequently, the respective top surfaces of frontside contact(s) 180 and ILD 176.1 may be coplanar.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. The frontside contact(s) 180 may be a part of the MOL.

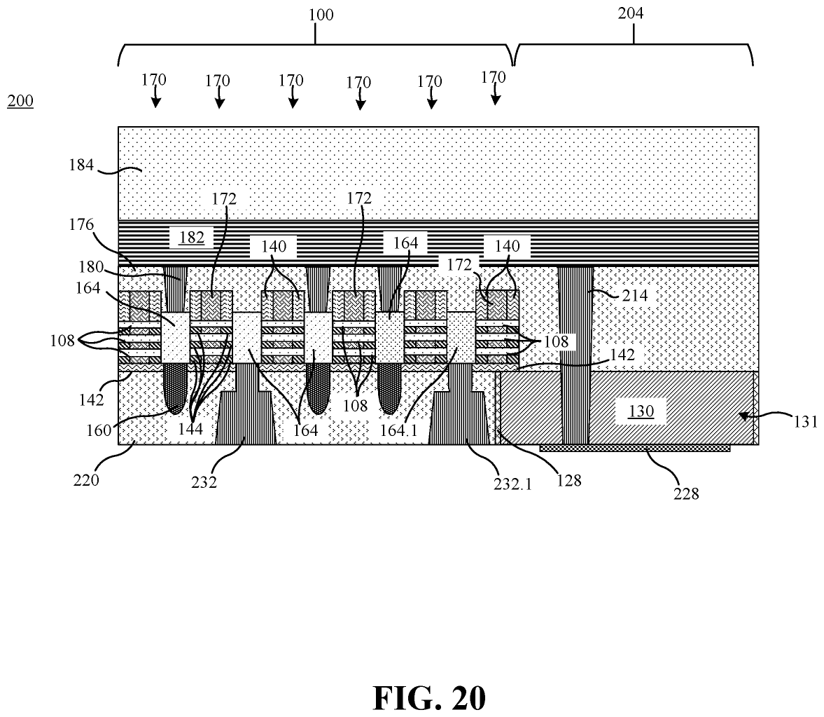

BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than one metal layers may be added in the BEOL. In the present example, there are multiple BEOL levels each on opposites sides of the semiconductor IC device 100. First, a frontside BEOL network 182 is formed on the frontside of the semiconductor device 100. Subsequently, a backside BEOL network 240, as depicted in FIG. 20 is formed.

In the depicted example, the frontside BEOL network 182 is formed over the ILD 176.1 and upon the frontside contact(s) 180. Respective wires within the frontside BEOL network 182 may be electrically connected to the one or more S/D regions 164, one or more replacement gate structure(s) 170 by a respective frontside contact 180. The frontside BEOL network 182 is located directly on the frontside surface of the MOL structure (e.g., ILD 176.1, frontside contacts 180, etc.). The frontside BEOL network 182 can include one or more interconnect dielectric material layers (including one of the dielectric materials mentioned above for the frontside ILD layer 176) and contains frontside metal wires (the metal wires can be composed of any electrically conductive metal or electrically conductive metal alloy) embedded therein. In some embodiments, the frontside metal wires within the frontside BEOL network 182 are composed of Cu. The frontside BEOL network 182 can include “x” numbers of frontside metal levels, wherein “x” is an integer starting from 1. The frontside BEOL network 182 may further contain conductive pads that are connected to one or more of the metal wires and may be used to connect the semiconductor IC device to an external and/or higher-level structure, such as a chip carrier, motherboard, or the like.

The carrier wafer 184 can include one of the semiconductor materials mentioned above for the semiconductor structure. Carrier wafer 184 may be attached to the semiconductor IC device 100 by a wafer-to-wafer bonding technique.

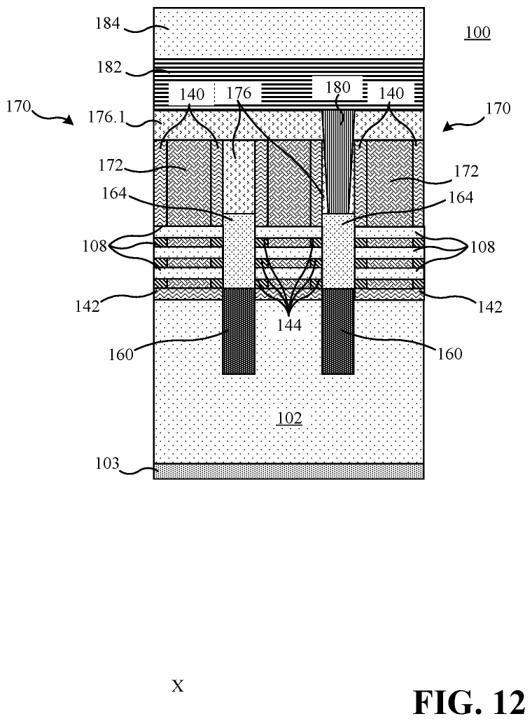

FIG. 12 depicts cross-sectional views of the semiconductor IC device 100 after fabrication operations, in accordance with embodiments of the present disclosure. In the depicted fabrication stages, substrate structure may be recessed. For example, the lower substrate 101 may be removed.

The substrate structure may be recessed by flipping the semiconductor IC device 100 (not shown) and removing the lower substrate 101 using any removal technique, such as a combination of wafer grinding, CMP, dry, and/or wet etch. In the example depicted, lower substrate 101 is removed by an etch that utilizes etch stop layer 103 as the etch stop. In this example, removal of lower substrate 101 exposes the bottom surface of etch stop layer 103.

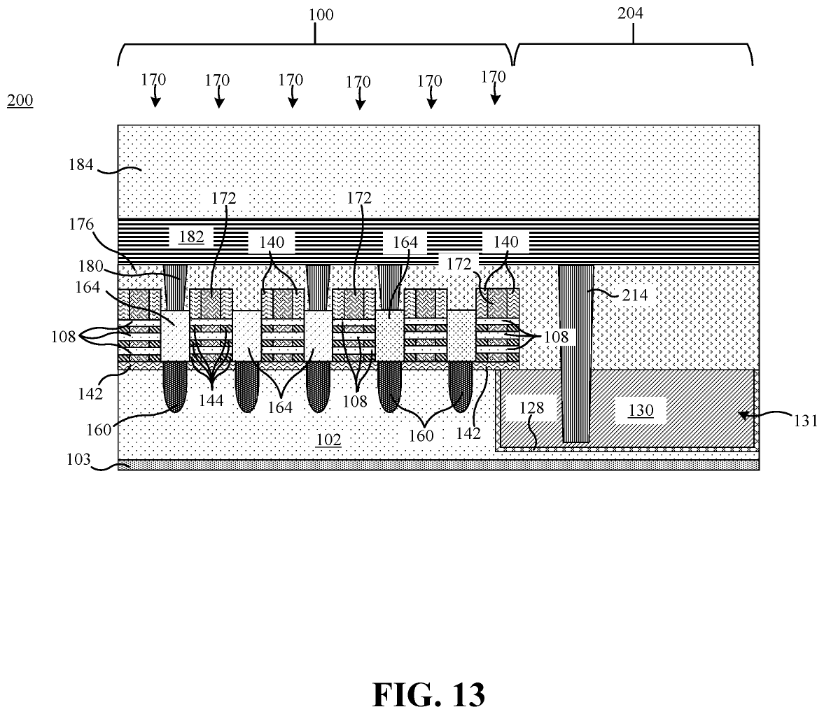

FIG. 13 depicts a cross-section view of semiconductor IC device 200 that is to include a fuse structure that is connected to at least a backside BEOL network, according to one or more embodiments of the disclosure. The Semiconductor IC device 200 is depicted at a similar fabrication stage relative to the semiconductor IC device 100 of FIG. 12.

Semiconductor IC device 200 has a semiconductor IC device region in which a semiconductor IC device 100 is formed and a fuse region 204 in which one or more fuse structures, that include at least a respective backside fuse wire 228, are formed.

Semiconductor IC device region includes semiconductor IC device 100 which has one or more FEOL microdevices, such as GAA FETs, which may be formed by the fabrication operations as described above.

Fuse region 204 may include STI region 131, deep via contact 214, ILD 176, ILD 176.1, or the like. The deep via contact 214 may be formed within the STI region 131 and within the ILD (e.g., 176, 176.1) of the semiconductor IC device. The deep via contact 214 may be formed along with the frontside contacts 180, in MOL fabrication stages. For example, a deep via contact etch (or a series of etches) may form a deep via contact opening within the ILD and within the underlying STI region. Next, conductive material may be formed within the deep via contact opening to form the deep via contact 214. A CMP may planarize the top surface of the semiconductor IC device 200 so that the respective top surfaces of the ILD, the frontside contacts 180, and the deep via contact 214. In this way, the frontside BEOL network 182 may be formed upon the deep via contact 214 as well as the frontside contact(s) 180. For clarity, each of the frontside contacts 180 and the deep via contact 214 may be connected to a respective frontside metal wire within the frontside BEOL network 182.

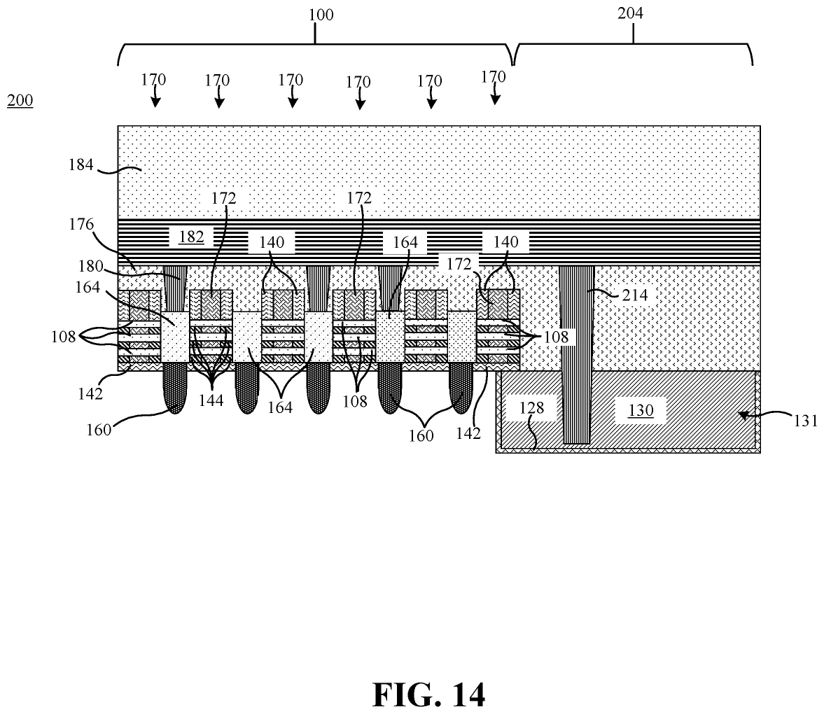

FIG. 14 depicts cross-sectional views of the semiconductor IC device 200 after fabrication operations, in accordance with embodiments of the present disclosure. In the depicted fabrication stages, the remaining substrate structure may be removed. For example, etch stop layer 103 and the upper substrate 102 may be removed.

The etch stop layer 103 may be removed by a subtractive removal technique such as a CMP, dry and/or wet etch. Upon removal of the etch stop layer 103, the bottom surface upper substrate 102 is exposed. The removal of etch stop layer 103 may be selective to the material of upper substrate 102. For example, etch stop layer 103 is removed by an etch that utilizes upper substrate 102 as the etch stop.

Subsequently, the upper substrate 102 is removed by an appropriate substrative removal technique, such as an etch, that removes associated portion(s) of the upper substrate 102. The etch may be timed or otherwise controlled to remove the material of substrate 102 and retain or otherwise expose the STI regions, retain and partially expose one or more backside contact placeholders 160, and retain and expose at least a portion of the BDI region 142.

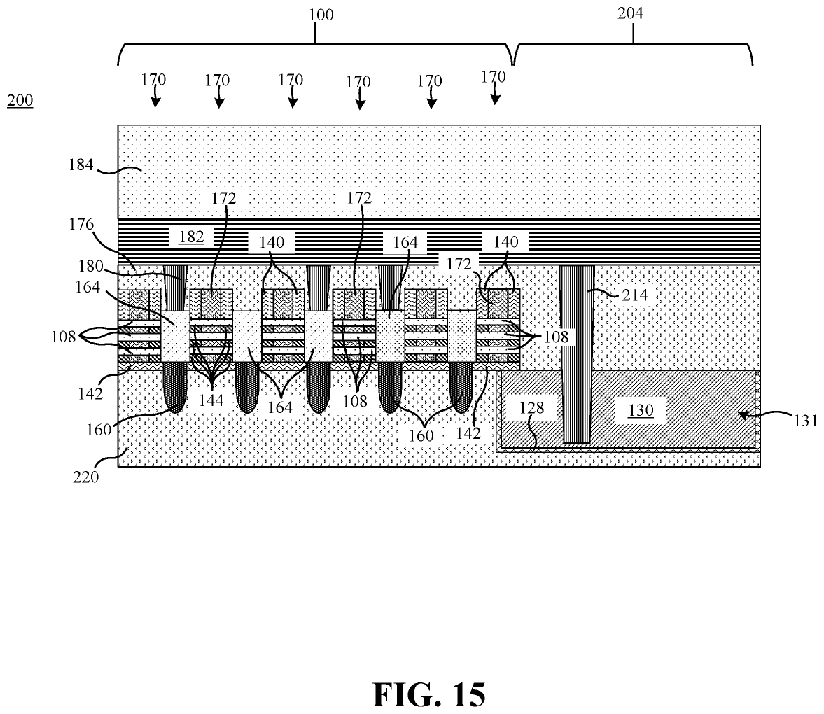

FIG. 15 depicts cross-sectional views of semiconductor IC device 200 shown after exemplary fabrication operation(s), in accordance with one or more embodiments. In the depicted fabrication stage, backside ILD 220 is formed upon the exposed backside of the semiconductor IC device 200.

The backside ILD 220 may be formed upon the bottom surfaces (as depicted) of the STI regions, upon the bottom surfaces (as depicted) one or more backside contact placeholders 160, and upon the bottom surfaces (as depicted) of the BDI region(s) 142. The backside ILD 220 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 220 can be utilized. The backside ILD 220 can be formed using, for example, CVD, PECVD, ALD, flowable CVD, spin-on dielectrics, or PVD.

In an example, the backside ILD 220 may be formed to a thickness below (as depicted) the bottom surface of the STI regions.

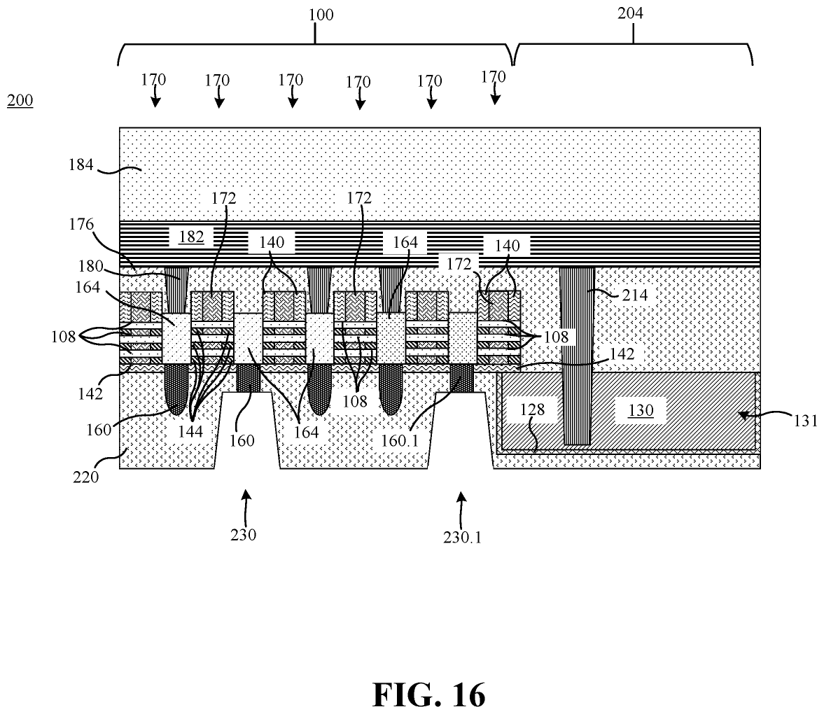

FIG. 16 depicts cross-sectional views of semiconductor IC device 200 shown after exemplary fabrication operation(s), in accordance with one or more embodiments. In the depicted fabrication stage, backside contact openings 230, 230.1 are formed within backside ILD 220. For clarity, a particular backside contact opening 230.1 is depicted and is associated with the predetermined backside contact placeholder 160.1 and is further associated with the backside contact 232.1 (depicted in FIG. 18) that positionally allows for the backside contact 232.1 to connect with the S/D region 164 located above the predetermined backside contact placeholder 160.

The backside contact openings 230, 230.1 may be formed by the same or shared lithography and etch process(es), or sequential lithography and etch processes. In such process(es), a mask may be applied to the backside of the backside ILD 220 and patterned. Openings in the patterned mask may expose the portion of the underlying backside ILD 220 to be removed while other protected portions of semiconductor IC device 200 may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention.

In the depicted example, within the semiconductor IC device region, the backside contact opening 230.1 is formed within backside ILD 220. This backside contact opening 230.1 further exposes the and/or partially removes a portion of the backside contact placeholder 160.1 there above (as depicted). Further in the depicted example, within the semiconductor IC device region, one or more backside contact openings 230 are formed within backside ILD 220 that expose a respective and/or partially removes a portion of the respective backside contact placeholder 160 there above (as depicted).

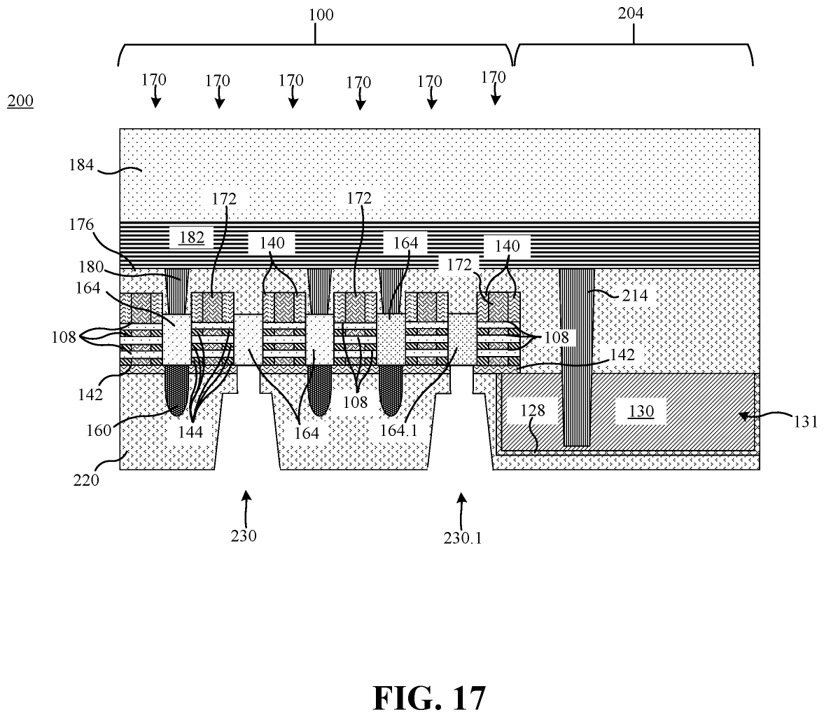

FIG. 17 depicts cross-sectional views of semiconductor IC device 200 shown after exemplary fabrication operation(s), in accordance with one or more embodiments. In the depicted fabrication stage, exposed backside contact placeholders 160 are removed. The exposed backside contact placeholders 160 may be removed by a substrative removal technique, such as an etch. In one example, the entire applicable contact placeholder 160 may be removed. In another example, the lower portion of the backside contact placeholder is removed using the etch stop layer top surface of the backside contact placeholder 160 as an etch stop to protect the S/D region 164 there above.

FIG. 18 depicts cross-sectional views of semiconductor IC device 200 shown after exemplary fabrication operation(s), in accordance with one or more embodiments. In the depicted fabrication stage, backside contacts 232, 232.1 are formed within the backside contact opening(s) 230.

For clarity, a particular backside contact 232.1 is depicted that is positionally located to connect with the to-be formed fuse wire and to the to-be formed backside BEOL network. The backside contacts 232, 232.1 may be formed by depositing conductive material, such as metal, into the respective backside contact opening(s) 230. In an example, backside contacts 232, 232.1 may be formed by depositing a liner, such as Ni, NiPt or Ti, etc. into the backside contact opening(s) 230, 230.1, depositing a metal adhesion liner, such as TiN, TaN, etc. upon the liner, and by depositing a conductive metal fill, such as Al, Ru, W, Co, Cu, etc. upon the metal adhesion liner.

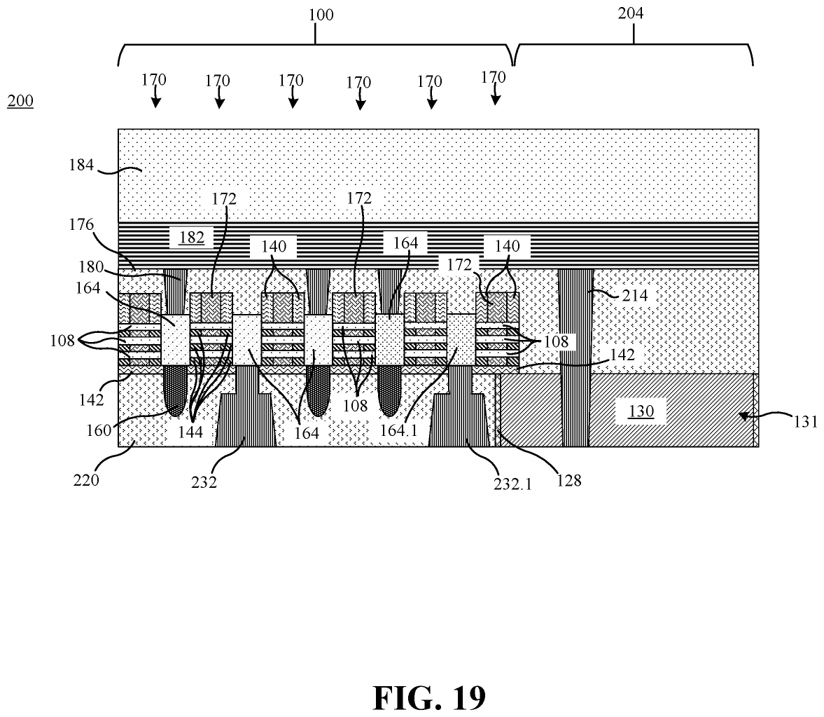

FIG. 19 depicts cross-sectional views of semiconductor IC device 200 shown after exemplary fabrication operation(s), in accordance with one or more embodiments. In the depicted fabrication stage, a planarization process, such as a CMP process or a mechanical grinding process, remove excess portions of the backside contacts 232, 232.1 and exposes at least a portion of the deep via contact 214. For example, the planarization process exposes a bottom surface (as depicted) of the deep via contact 214. Subsequently, the respective bottom surfaces (as depicted) of backside contacts 232, 232.1, deep via contact 214, STI region(s) 131, and backside ILD 220 may be substantially horizontal and/or substantially coplanar.

FIG. 20 depicts cross-sectional views of semiconductor IC device 200 shown after exemplary fabrication operation(s), in accordance with one or more embodiments. In the depicted fabrication stage, backside fuse wire 228 is formed. The backside fuse wire 228, which may also be referred to herein as fuse wire 228, is formed upon the respective bottom surfaces of the backside ILD 220, STI region(s) 131, and the deep via contact 214 (as depicted) within fuse region 204.

Fuse wire 228 is formed of conductive material and may be formed by a deposition process such as CVD, plating, or the like. The fuse wire 228 may be formed by lithography and etch process(es). In such process(es), a mask may be applied and patterned. Backside wire opening(s) in the patterned mask may expose the respective locations upon ILD 220, STI region, and the deep via contact 214 to which the backside wires are to be formed while other protected portions of semiconductor IC device 200 thereunder may be protected from backside wire formation thereupon.

Fuse wire 228 may be further formed by depositing conductive material such as metal into the respective backside wire opening(s). In an example, the fuse wire 228 may be formed by depositing a conductive metal fill, such as Al, Ru, W, Co, Cu, etc. within the backside wire opening(s). Subsequently, a substrative removal technique, such as an etch or series of etches, may remove excess portions of the conductive material and the shared mask.

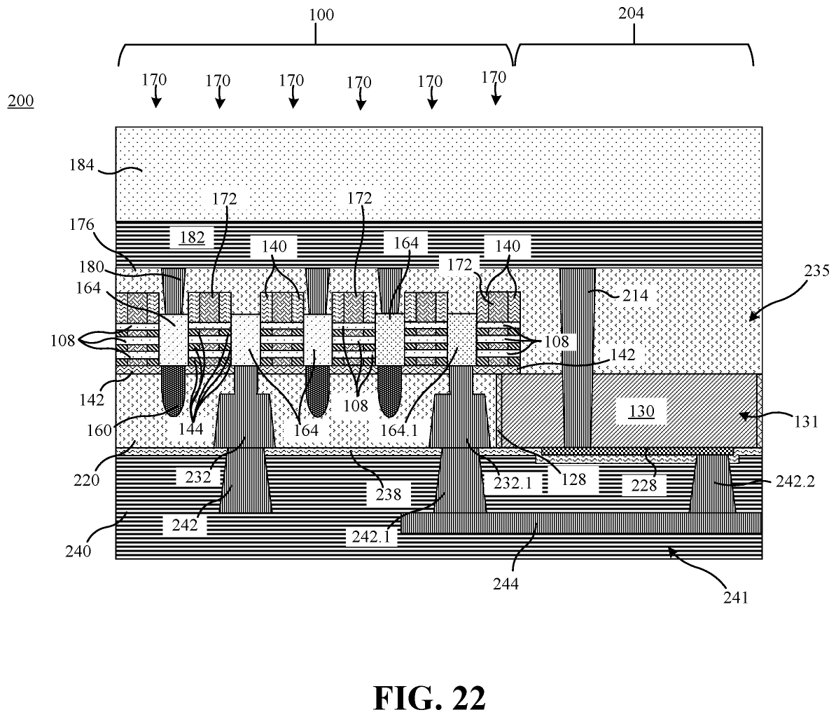

Fuse wire 228 is located within fuse region 204. Fuse wire 228 is further located vertically between the backside BEOL network 240 (show in FIG. 22) and the one or more FEOL microdevices (e.g., one or more GAA FETs). A first end surface of fuse wire 228 may be horizontally inset relative to a predetermined backside contact 232.1, as depicted. This predetermined backside contact 232.1 positionally allows for such backside contact to connect with both the fuse wire 228 by way of the backside BEOL network 240 and the S/D region 164 located there above.

Because fuse wire 228 may be fabricated upon the planarized bottom surface of the semiconductor IC structure of the previous drawing, the bottom surface of fuse wire 228 may be below the bottom surface of the backside contact 232.1 (as depicted). Similarly, the top surface of fuse wire 228 may be substantially coplanar with the bottom surface of the backside contact 232.1 (as depicted).

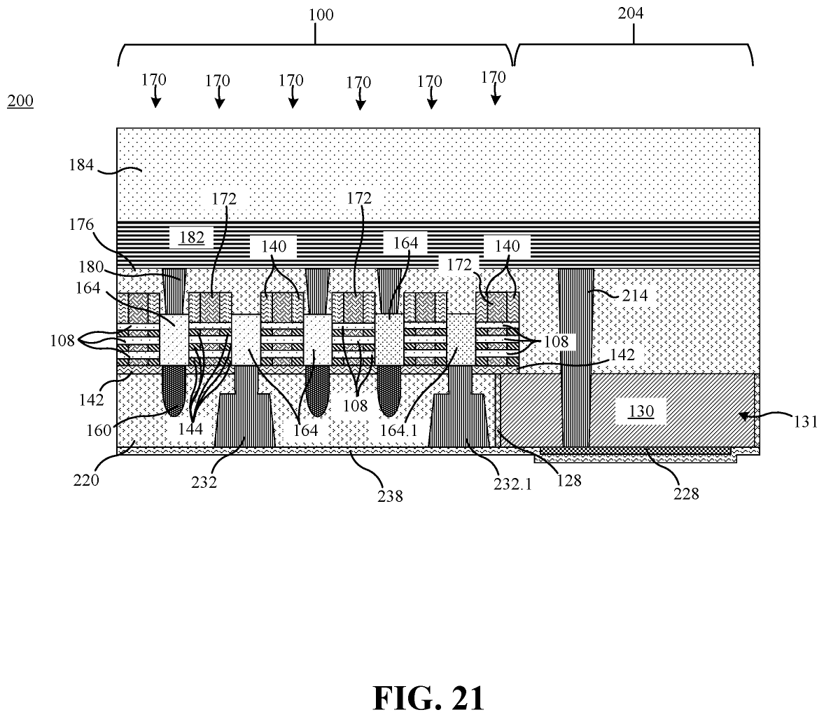

FIG. 21 depicts cross-sectional views of semiconductor IC device 200 shown after exemplary fabrication operation(s), in accordance with one or more embodiments. In the depicted fabrication stage, backside capping layer 238 is formed upon the exposed backside of the semiconductor IC device 200.

The backside capping layer 238 may be formed upon the bottom surfaces (as depicted) of the STI regions 131, upon the bottom surfaces (as depicted) one or more backside contacts 232, 232.1, upon the bottom surfaces of the backside ILD 220, and upon the backside and around the fuse wire 228. The backside capping layer 238 may be formed by depositing a dielectric material, such as, for example, porous silicates, carbon doped oxides, silicon dioxides, silicon nitrides, silicon oxynitrides, or other dielectric materials. Any appropriate deposition technique for forming the backside capping layer 238 can be utilized. The backside capping layer 238 can be formed using, for example, CVD, PECVD, ALD, flowable CVD, spin-on dielectrics, or PVD. In a particular embodiment, the backside capping layer 238 may be a different material relative to the backside ILD 220. For example, the backside capping layer 238 may be a silicon nitride and the backside ILD 220 may be a silicon dioxide. In an example, the backside capping layer 238 a vertical thickness ranging, for example, from approximately 3 nm to approximately 20 nm. In certain embodiments, the backside capping layer 238 has a vertical thickness ranging, for example, from approximately 3 nm to approximately 10 nm.

FIG. 22 depicts cross-sectional views of semiconductor IC device 200 shown after exemplary fabrication operation(s), in accordance with one or more embodiments. In the depicted fabrication stage, a backside BEOL network 240 is formed.

The backside BEOL network 240 is formed over the backside capping layer 238 and upon the one or more backside contacts 232, 232.1. The backside BEOL network 240 may be indirectly electrically and/or indirectly physically connected to the one or more S/D regions 164 by way of a particular backside contact 232. The backside BEOL network 240 is located directly on the backside surface of backside ILD 220, backside contacts 232, 232.1, etc.

The backside BEOL network 240 can include one or more interconnect dielectric material layers (including one of the dielectric materials mentioned above for the ILD layer 176) and contains backside metal wires embedded therein. In some embodiments, the backside metal wires within the backside BEOL network 240 are composed of Cu. The backside BEOL network 240 can include “x” numbers of backside metal levels, wherein “x” is an integer starting from 1. If not included in frontside BEOL network 182, backside BEOL network 240 may further contain conductive pads that are connected to one or more of the backside metal wires and may be used to connect the semiconductor IC device 200 to the external and/or higher-level structure.

In an example, signal routing and power routing is effectively split between the frontside BEOL network 182 and the backside BEOL network 240. For example, at least 90% of the frontside metal wires (e.g., furthest from the transistor(s)) are signal routing metal wires and the remainder frontside metal wires which are usually present in metal levels closest to the transistor, can be used as power routing wires. Further in this example, at least 90% of the backside metal wires that are in metal levels closest to the transistor(s) are power routing metal wires and the remainder backside metal wires which are usually present in metal levels furthest away from the transistor, can be used as signal routing wires. Power routing wires may be less dense signal routing wires. A signal routing wire is defined herein as a conductive feature, such as a wire, trace, or the like, that is configured to electrically carry a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like. For clarity, in some examples, the backside BEOL network 240 may be a backside power distribution network (BSPDN).

The backside BEOL network 240 includes various wiring levels. The wiring levels may alternate between a via level and a metal level. To form a via level, an associated dielectric passivation layer may be formed, the dielectric passivation layer may be patterned to create a via opening therein, and conductive or metal material may be deposited within the via opening to form a via contact. A via, such as via contact 242, via contact 242.1, 242.2, within a lowest via level may connect either directly or indirectly to an associated structure. For example, via contact 242 may directly connect to backside contact 232, via contact 242.1 may directly connect to backside contact 232.1, and via contact 242.2 may directly connect to fuse wire 228.

To form a metal level, an associated dielectric passivation layer may be formed, the dielectric passivation layer may be patterned to create a wiring trench therein, and conductive or metal material may be deposited within the wiring trench to form a wire. A wire, such as backside wire 244 within a lowest metal level may connect directly one or more via contacts, such as via contact 242.1 and to via contact 242.2. For clarity, a conductive pathway 241 within the backside BEOL network 240 may be formed by one or more via contacts and one or more metal wires within one or more various levels within the backside BEOL network 240. The conductive pathway 241 is generally connected to backside contact 232.1 and to the fuse wire 228. Though the conductive pathway 241 is depicted with vias 242.1, 242.2 in the lowest via level and metal wire 244 located in the lowest metal level within backside BEOL network 240, the electrical pathway 241 may include contact vias (in the same or different level), multiple wires (in the same or different levels), or the like and be located in higher levels, be located within multiple levels, or the like.

For clarity, semiconductor IC device 200 includes a fuse structure 235 in a non-programmed state that is connected to conductive pathway 241 that is in backside BEOL network 240. Semiconductor IC device 200 may further include a backside contact 232.1 that is connected to transistor and that is connected to the conductive pathway 241. The fuse structure 235 is further connected to deep via contact 214 which is also connected to frontside BEOL network 182.

The fuse structure 235 includes fuse wire 228 and the deep via contact 214. The fuse wire 228 is located vertically between the transistor and the backside BEOL network 240 and is connected to conductive pathway 241 and to the deep via contact 232. The deep via contact 232 is also connected to the frontside BEOL network 182.

In the non-programmed state of the fuse structure 235, the fuse structure 235 may be utilized for routing current for transistor operation(s). For example, when a voltage that is greater than the threshold voltage of the transistor is applied to its gate, electrical current flows through the one or more channels, and between the source and drain. In other words, in the non-programmed state of the fuse structure 235, current may flow through the transistor and through the deep via contact 214 and through the frontside BEOL network 182 by way of the backside BEOL network 240 and the fuse wire 228. In other words, in the non-programmed state of the fuse structure 235, the fuse structure 235 may be used to route current between frontside BEOL network 182 and backside BEOL network 240.

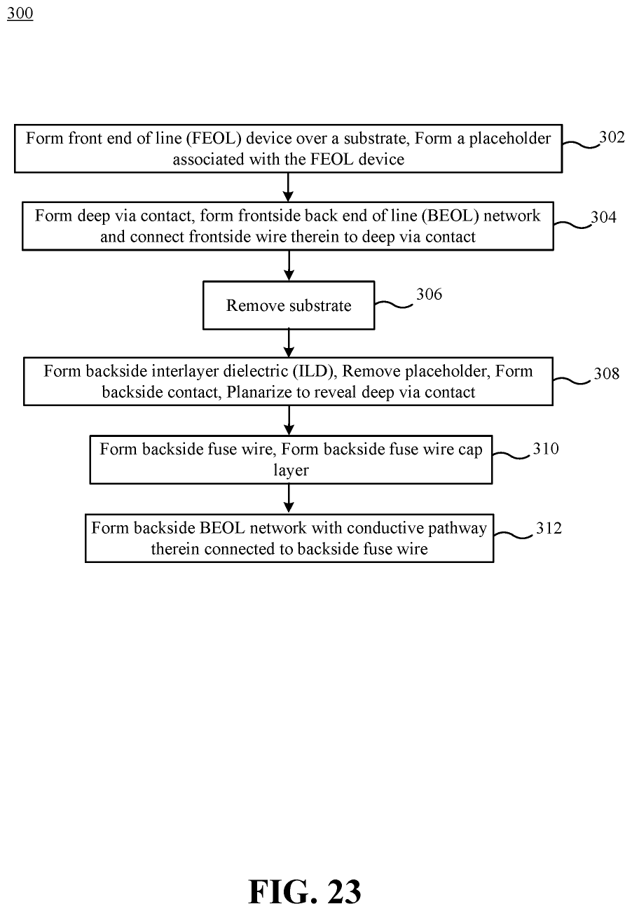

FIG. 23 depicts a flow diagram illustrating method 300 to fabricate a semiconductor IC device, such as semiconductor IC device 200. The depicted fabrication operations of method 300 are illustrated and described above with reference to one or more of FIG. 2 through FIG. 22 of the drawings, which describe the fabrication of semiconductor IC device 100 and the fabrication of semiconductor IC device 200, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming a FEOL device over a substrate and forming a placeholder associated with the FEOL device. For example, method 300 may include forming a backside contact placeholder 160 and may include forming a GAA FET that includes active nanolayer 108 channels, S/D regions 164, replacement gate structure 170, and the like.

At block 304, method 300 may further continue with forming a deep via contact and with forming a frontside BEOL network that includes a frontside wire therein that is connected to the deep via contact. For example, deep via contact 214 is formed along with frontside contact 180 that contacts one of the S/D regions 164.1 of the GAA FET transistor. Subsequently, frontside BEOL network 182 is formed upon the frontside of the semiconductor IC device. The frontside BEOL network 182 includes a first routing wire (e.g., signal routing wire or power routing wire) that is connected to the deep via contact 214.

At block 306, method 300 may further continue with removing the substrate. For example, lower substrate 101, etch stop layer 103, and upper substrate 102 may be removed which may expose the backside contact placeholder 160.

At block 308, method 300 may further include forming a backside ILD, removing the placeholder(s), forming one or more backside contact(s), and planarizing the backside of the semiconductor IC device to reveal the backside of the deep via contact. For example, backside ILD 220 is formed upon the backside of the semiconductor IC device 200 around the backside contact placeholder 160 and around the deep via contact 214 and the backside of the semiconductor IC device 200 is planarized to remove excess backside ILD 220 material and to reveal the backside of the deep via contact 214. Subsequently, ILD 220 may be patterned to form backside contact openings 230 and a respective backside contact 232 may be formed within a particular backside opening. Subsequently, a CMP process may remove excess backside contact 232 material and may further expose the deep via contact 214.

At block 310, method 300 may continue with forming a backside fuse wire in contact with the deep via contact and with forming a backside wire cap layer. For example, fuse wire 228 is formed upon the revealed backside of the deep via contact 214 and backside capping layer 238 is formed upon the fuse wire 228.

At block 312, method 300 may continue with the forming a backside BEOL network and forming a conductive pathway therein that is connected to the backside fuse wire. For example, the backside BEOL network 240 is formed upon the backside of semiconductor IC device 200 with the conductive pathway 241 therein that is connected to the fuse wire 228.

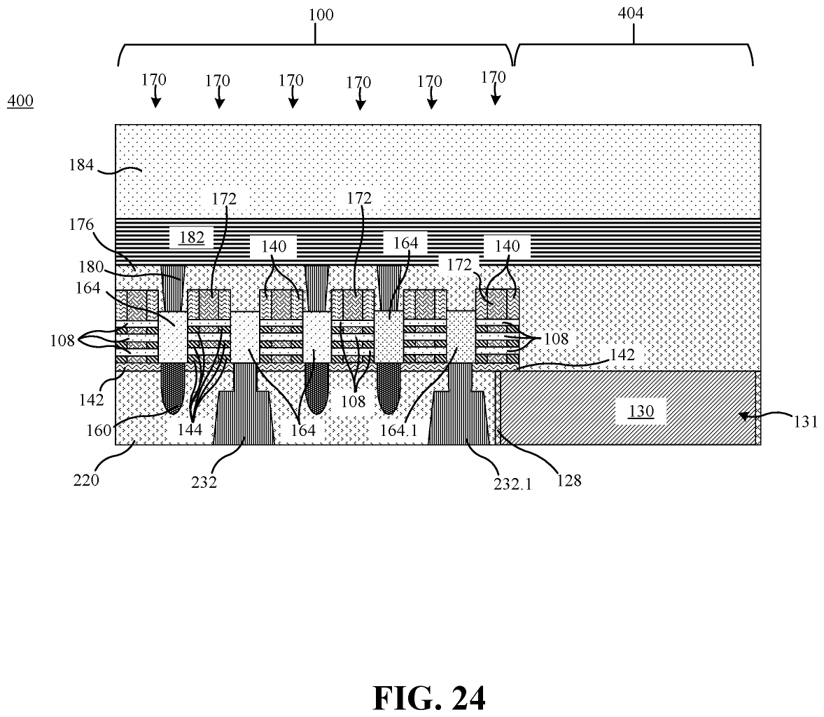

FIG. 24 depicts a cross-section view of semiconductor IC device 400 that is to include a fuse structure that is connected to at least a backside BEOL network, according to one or more embodiments of the disclosure. The semiconductor IC device 400 is depicted at a similar fabrication stage relative to the semiconductor IC device 200 of FIG. 20 and previous fabrications stages to fabricate semiconductor IC device 200 may be utilized to also fabricate the semiconductor IC device 400 depicted. For clarity, semiconductor IC device 400 may be like semiconductor IC device 200 but without the deep via contact 214. Semiconductor IC device 400 has a semiconductor IC device region in which a semiconductor IC device 100 is formed and a fuse region 404 in which one or more fuse structures are formed.

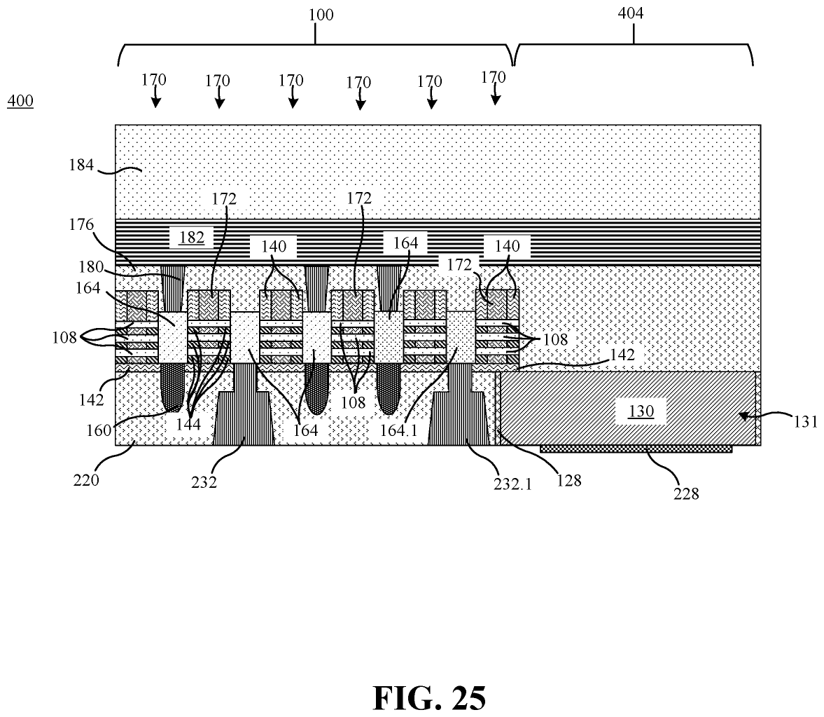

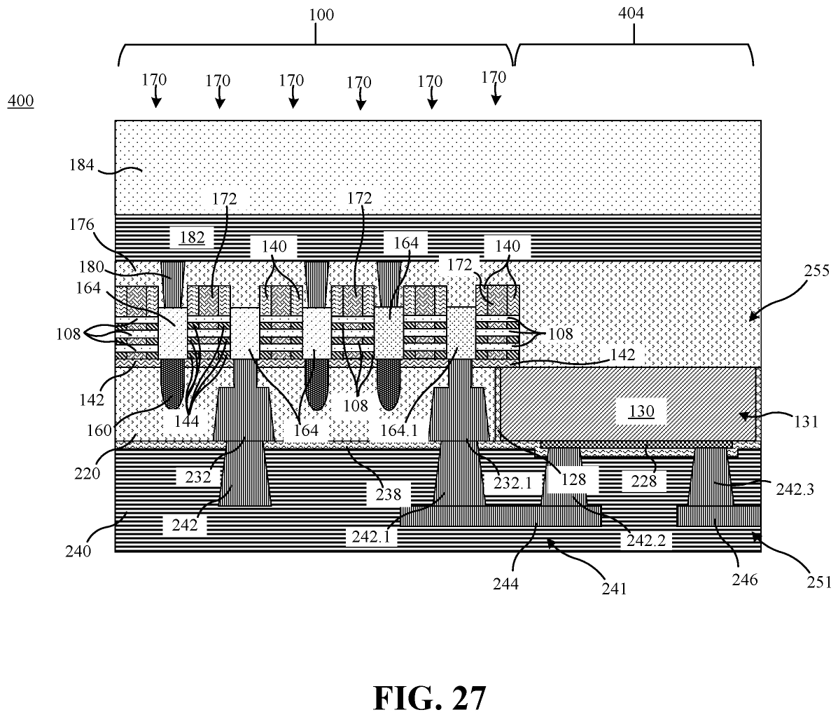

In the depicted fabrication stage shown in FIG. 25, backside fuse wire 228 is formed upon the respective bottom surfaces (as depicted) of the backside ILD 220 and/or STI region(s) 131 within fuse region 404. Some details relating to the backside fuse wire 228 been presented above and are not repeated. Fuse wire 228 is located within fuse region 404 and is further located vertically between the backside BEOL network 240 (show in FIG. 27) and the one or more FEOL microdevices (e.g., one or more GAA FETs). A first end surface of fuse wire 228 may be horizontally inset relative to a predetermined backside contact 232.1, as depicted. This predetermined backside contact 232.1 positionally allows for backside contact 232.1 to connect with both the fuse wire 228, by way of the backside BEOL network 240, and the S/D region 164.1 there above.

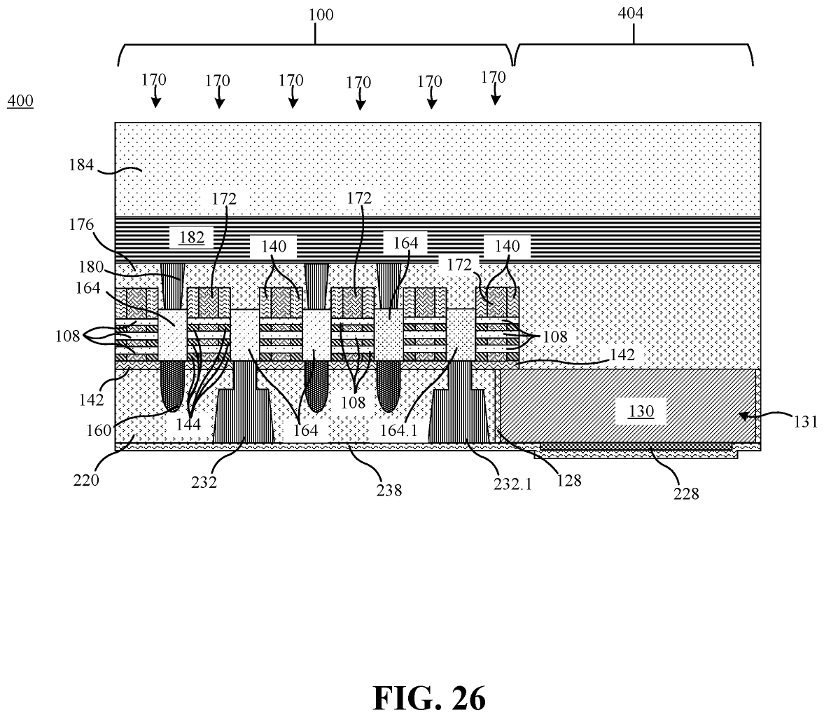

FIG. 26 depicts a cross-sectional view of semiconductor IC device 400 shown after exemplary fabrication operation(s), in accordance with one or more embodiments. In the depicted fabrication stage, backside capping layer 238 is formed upon the exposed backside of the semiconductor IC device 400.

The backside capping layer 238 may be formed upon the bottom surfaces (as depicted) of the STI regions 131, upon the bottom surfaces (as depicted) one or more backside contacts 232, 232.1, upon the bottom surfaces backside ILD 220, and upon the backside and around the fuse wire 228. Details relating to the backside capping layer 238 have been presented above and are not repeated.

FIG. 27 depicts a cross-sectional view of semiconductor IC device 400 shown after exemplary fabrication operation(s), in accordance with one or more embodiments. In the depicted fabrication stage, a backside BEOL network 240 is formed. Some details relating to the backside BEOL network 240 have been presented above and are not repeated.

The backside BEOL network 240 includes various wiring levels. The wiring levels may alternate between a via level and a metal level. To form a via level, an associated dielectric passivation layer may be formed, the dielectric passivation layer may be patterned to create a via opening therein, and conductive or metal material may be deposited within the via opening to form a via contact. A via, such as via contact 242, via contact 242.1, 242.2, and 242.3 within a lowest via level may connect either directly or indirectly to an associated structure. For example, via contact 242 may directly connect to backside contact 232, via contact 242.1 may directly connect to backside contact 232.1, via contact 242.2 may directly connect to fuse wire 228, and via contact 242.3 may directly connect to fuse wire 228.

To form a metal level, an associated dielectric passivation layer may be formed, the dielectric passivation layer may be patterned to create a wiring trench therein, and conductive or metal material may be deposited within the wiring trench to form a wire. A wire, such as backside wire 244 and backside wire 246 within a lowest metal level may connect directly one or more via contacts, such as via contacts 242.1, 242.2, and 242.3, respectively. For clarity, a conductive pathway 241 within the backside BEOL network 240 may be formed by one or more via contacts and one or more metal wires within one or more various levels within the backside BEOL network 240. The conductive pathway 241 is generally connected to backside contact 232.1 and to the fuse wire 228. Further, a conductive pathway 251 different from the conductive pathway 241 within the backside BEOL network 240 may be formed by one or more via contacts and one or more metal wires within one or more various levels within the backside BEOL network 240. The conductive pathway 251 is generally connected to the fuse wire 228.

Though the conductive pathway 241 is depicted with vias 242.1, 242.2 in the lowest via level and metal wire 244 located in the lowest metal level within backside BEOL network 240, the electrical pathway 241 may include contact vias (in the same or different level), multiple wires (in the same or different levels), or the like and may be in higher levels, may be located within multiple levels, or the like. Similarly, the conductive pathway 251 is depicted with via 242.3 in the lowest via level and metal wire 246 located in the lowest metal level within backside BEOL network 240. However, the electrical pathway 251 may include contact vias (in the same or different level), multiple wires (in the same or different levels), or the like, and may be in higher levels, may be in multiple levels, or the like.

For clarity, semiconductor IC device 400 includes fuse structure 255 in a non-programmed state that is connected to conductive pathway 241 that is in backside BEOL network 240. Semiconductor IC device 400 may further include a backside contact 232.1 that is connected to a transistor and that is connected to the conductive pathway 241. The fuse structure 255 is further connected to a different conductive pathway 251 also within the backside BEOL network 240.

The fuse structure 255 includes fuse wire 228. The fuse wire 228 is located vertically between the transistor and the backside BEOL network 240 and is connected to conductive pathway 241 and conductive pathway 251. In the non-programmed state of the fuse structure 255, the fuse structure 255 may be utilized for routing current for transistor operation(s). For example, when a voltage that is greater than the threshold voltage of the transistor is applied to its gate, electrical current flows through the one or more channels, and between the source and drain. In other words, in the non-programmed state of the fuse structure 255, current may flow through the transistor and through the backside BEOL network 240 by way of the fuse wire 228. In other words, in the non-programmed state of the fuse structure 255, the fuse structure 255 may be used to route current between different conductive pathways within the backside BEOL network 240.

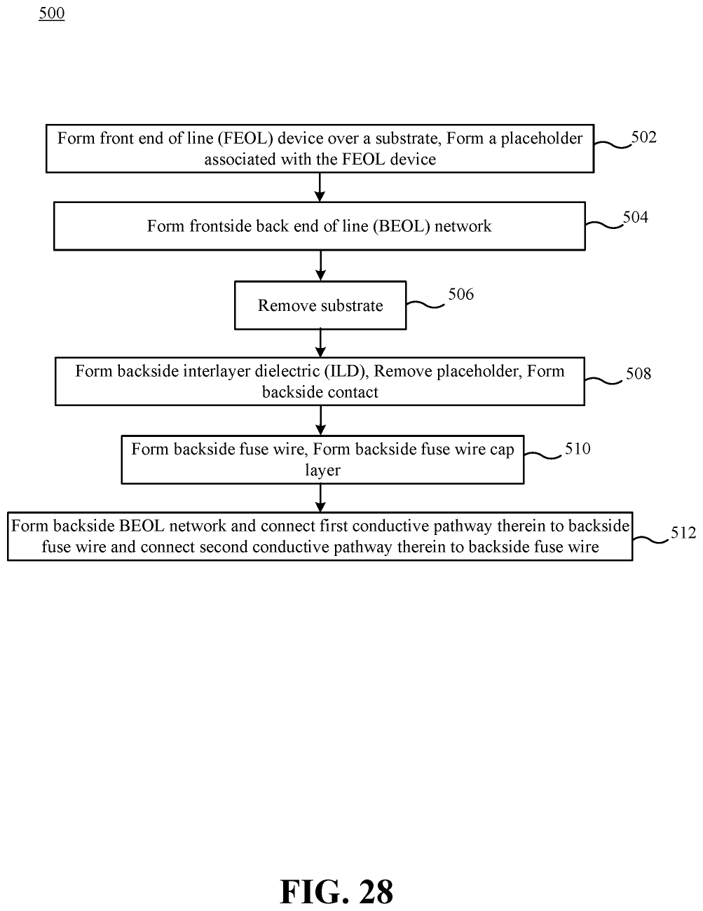

FIG. 28 depicts a flow diagram illustrating method 500 to fabricate a semiconductor IC device, such as semiconductor IC device 400. The depicted fabrication operations of method 500 are illustrated and described above with reference to one or more of the drawings, which describe the fabrication of semiconductor IC device 100 and the fabrication of semiconductor IC device 400, though the fabrication operations described in method 500 may be used to fabricate other types of semiconductor IC devices. The method 500 depicted herein is illustrative. There can be many variations to the diagram or operations described therein without departing from the spirit of the embodiments. For instance, the operations can be performed in a differing order, or operations can be added, deleted, or modified.

At block 502, method 500 may begin with forming a FEOL device over a substrate and forming a placeholder associated with the FEOL device. For example, method 500 may include forming a backside contact placeholder 160 and may include forming a GAA FET that includes active nanolayer 108 channels, S/D regions 164, replacement gate structure 170, or the like.

At block 504, method 500 may further continue with forming frontside contact(s) and with forming a frontside BEOL network. For example, frontside contacts are formed, such as frontside contact 180 that contacts one of the S/D regions 164.1 of the GAA FET transistor. Subsequently, frontside BEOL network 182 is formed upon the frontside of the semiconductor IC device.

At block 506, method 500 may further continue with removing the substrate. For example, lower substrate 101, etch stop layer 103, and upper substrate 102 may be removed which may expose the backside contact placeholder 160.

At block 508, method 500 may further include forming a backside ILD, removing the placeholder(s), forming one or more backside contact(s), and planarizing the backside of the semiconductor IC device. For example, backside ILD 220 is formed upon the backside of the semiconductor IC device 400 around the backside contact placeholder 160 and around the deep via contact 214 and the backside of the semiconductor IC device 400 is planarized to remove excess backside ILD 220 material. Subsequently, ILD 220 may be patterned to form backside contact openings 230 and a respective backside contact 232 may be formed within a particular backside opening. Subsequently, a CMP process may remove excess backside contact 232 material.

At block 510, method 500 may continue with forming a backside fuse wire in contact and with forming a backside wire cap layer. For example, fuse wire 228 is formed upon the revealed backside of the deep via contact 214 and backside capping layer 238 is formed upon the fuse wire 228.

At block 512, method 500 may continue with the forming a backside BEOL network and forming two or more conductive pathways therein that is connected to the backside fuse wire. For example, the backside BEOL network 240 is formed upon the backside of semiconductor IC device 400 with the conductive pathway 241 and with the conductive pathway 251 therein that are both connected to the fuse wire 228.

Semiconductor IC device 200, 400, or the like, may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a front end of line (FEOL) microdevice;
a frontside back end of line (BEOL) network;
a fuse structure comprising a deep via contact directly connected to a fuse wire and directly connected to the frontside BEOL network;
a backside contact that is connected to the FEOL microdevice; and
a backside BEOL network comprising a conductive pathway directly connected to the backside contact and directly connected to the fuse wire.

2. The semiconductor IC device of claim 1, wherein the fuse wire is vertically between the deep via contact and the backside BEOL network.

3. The semiconductor IC device of claim 1, wherein a top surface of the fuse wire is directly connected to a bottom surface of the deep via contact.

4. The semiconductor IC device of claim 1, wherein a bottom surface of the fuse wire is directly connected to the conductive pathway.

5. The semiconductor IC device of claim 1, wherein a bottom surface of the backside contact is directly connected to the conductive pathway.

6. The semiconductor IC device of claim 1, wherein, when the fuse structure is in a non-programmed state, the fuse wire enables the routing of current through the FEOL microdevice, through the backside BEOL network, and through the frontside BEOL network.

7. The semiconductor IC device of claim 1, wherein, when the fuse structure is in a programmed state, an open circuit exists within the fuse wire that prevents the fuse wire from routing current between the frontside BEOL network and the backside BEOL network.

8. The semiconductor IC device of claim 1, wherein the conductive pathway comprises a plurality of contact vias and one or more backside wires.

9. The semiconductor IC device of claim 1, wherein a bottom surface of the fuse wire is vertically below a bottom surface of the backside contact.

10. The semiconductor IC device of claim 1, wherein the fuse wire is below a shallow trench isolation (STI) region.

11. The semiconductor IC device of claim 1, wherein a top surface of the fuse wire is coplanar with a bottom surface of the backside contact.

12. A semiconductor integrated circuit (IC) device comprising:
a front end of line (FEOL) microdevice;
a backside contact that is connected to the FEOL microdevice;
a fuse wire; and
a backside BEOL network comprising a first conductive pathway directly connected to the backside contact and directly connected to the fuse wire and a second conductive pathway directly connected to the fuse wire.

13. The semiconductor IC device of claim 12, wherein the fuse wire is vertically between the backside contact and the backside BEOL network.

14. The semiconductor IC device of claim 12, wherein a bottom surface of the fuse wire is directly connected to the first conductive pathway.

15. The semiconductor IC device of claim 12, wherein a bottom surface of the fuse wire is directly connected to the second conductive pathway.

16. The semiconductor IC device of claim 12, wherein a bottom surface of the backside contact is directly connected to the first conductive pathway.

17. The semiconductor IC device of claim 12, wherein, when the fuse wire is in a non-programmed state, the fuse wire enables the routing of current through the FEOL microdevice, through the backside BEOL network between the first conductive pathway and the second conductive pathway.

18. The semiconductor IC device of claim 12, wherein, when the fuse wire is in a programmed state, an open circuit exists within the fuse wire that prevents the fuse wire from routing current between the first conductive pathway and the second conductive pathway.

19. The semiconductor IC device of claim 12, wherein a top surface of the fuse wire is coplanar with a bottom surface of the backside contact.

20. A semiconductor integrated circuit (IC) device method comprising:
programming a fuse structure that comprises a fuse wire and a deep via contact, wherein the deep via contact is directly connected to the fuse wire and directly connected to a frontside back end of the line (BEOL) network, wherein the fuse wire is connected to a conductive pathway within a backside BEOL network; and
as a result of programming the fuse structure, preventing current flow between the frontside BEOL network and the backside BEOL network through the fuse wire.
